(19) United States
(12) Patent Application Publication
(10) Pub. No.: US 2025/0142833 A1
(43) Pub. Date: May 1, 2025

(54) THREE-DIMENSIONAL MEMORY DEVICES AND FABRICATING METHODS THEREOF

(71) Applicant: YANGTZE MEMORY TECHNOLOGIES CO., LTD., Wuhan (CN)

(72) Inventors: Dongxue Zhao, Wuhan (CN); Zhong Zhang, Wuhan (CN); Changzhi Sun, Wuhan (CN); Wenxi Zhou, Wuhan (CN); Zhiliang Xia, Wuhan (CN)

(21) Appl. No.: 18/387,772

(22) Filed: Nov. 7, 2023

(30) Foreign Application Priority Data
Nov. 1, 2023 (CN) 202311452186.X

(51) Int. Cl. H10B 51/30; H10B 51/10; H10B 51/20

(52) U.S. Cl. CPC H10B 51/30; H10B 51/10; H10B 51/20

(57) ABSTRACT

A semiconductor structure comprises layers of transistors stacked in a vertical direction. Each layer of transistors comprises: a first array of transistors sharing a first common first-type terminal line; a second array of transistors sharing a second common first-type terminal line. The first array of transistors and the second array of transistors share a common second-type terminal line. The semiconductor structure further comprises a first common first-type terminal contact structure coupled with the first common first-type terminal line in a first first-type terminal contact region, a second common first-type terminal contact structure coupled with the second common first-type terminal line in a second first-type terminal contact region, and a common second-type terminal contact structure coupled with the common second-type terminal line in a common second-type terminal contact region.

### CROSS-REFERENCE TO RELATED APPLICATIONS

This application claims the benefit of priority to Chinese Application No. 202311452186.X, filed on Nov. 1, 2023, which is incorporated herein by reference in its entirety.

### TECHNICAL FIELD

The present disclosure generally relates to the field of semiconductor technology, and more particularly, to three-dimensional (3D) Random Access Memory (RAM) devices, and fabricating methods thereof.

### BACKGROUND

As memory devices are shrinking to smaller die sizes to reduce manufacturing cost and increase storage density, scaling of planar memory cells faces challenges due to process technology limitations and reliability issues. A three-dimensional (3D) memory architecture can address the density and performance limitation in planar memory cells.

### BRIEF SUMMARY

Implementations of 3D memory devices and fabricating methods are described in the present disclosure.

One aspect of the present disclosure provides a semiconductor structure, comprising: a plurality of layers of transistors stacked in a vertical direction, each layer of transistors comprising: a first array of transistors sharing a first common first-type terminal line; a second array of transistors sharing a second common first-type terminal line, wherein the first array of transistors and the second array of transistors share a common second-type terminal line; and a plurality of contact structures comprising: a first common first-type terminal contact structure coupled with the first common first-type terminal line in a first first-type terminal contact region located on a first lateral side of the first array of transistors away from the second array of transistors, a second common first-type terminal contact structure coupled with the second common first-type terminal line in a second first-type terminal contact region located on a second lateral side of the second array of transistors away from the first array of transistors, and a common second-type terminal contact structure coupled with the common second-type terminal line in a common second-type terminal contact region located between the first array of transistors and the second array of transistors.

In some implementations, the transistors are ferroelectric field-effect transistors (FeFET).

In some implementations, each FeFET comprises: a channel layer; a ferroelectric layer having ferroelectricity and encircled by the channel layer in a horizontal plane; and a gate encircled by the ferroelectric layer in the horizontal plane.

In some implementations, the channel layer comprises a metal oxide semiconductor material.

In some implementations, the channel layer of each FeFET has an oval-ring shape in a horizontal plane.

In some implementations, a first portion of the channel layer at a second end of the long diameter of the oval shape is in contact with the first common first-type terminal line or the second common first-type terminal line; and a second portion of the channel layer at a first end of a long diameter of the oval shape is in contact with the common second-type terminal line.

In some implementations, the first common first-type terminal line comprises a first U-shape portion located between adjacent rows of the first array of transistors and with a first opening opposite towards the second array of transistors; the second common first-type terminal line comprises a second U-shape portion located between adjacent rows of the second array of transistors and with a second opening opposite towards the first array of transistors.

In some implementations, the first-type terminal is a drain terminal; the second-type terminal is a source terminal; the first common first-type terminal contact structure is connected to a first bit line; the second common first-type terminal contact structure is connected to a second bit line, and the common second-type terminal contact structure is connected to a source line.

In some implementations, each of the plurality of contact structures is located in a dielectric stack in the first first-type terminal contact region, or the second first-type terminal contact region, or the common second-type terminal contact region.

In some implementations, the first common first-type terminal lines of the plurality of layers of transistors overlap in the vertical direction; the second common first-type terminal lines of the plurality of layers of transistors overlap in the vertical direction; and the common second-type terminal lines of the plurality of layers of transistors overlap in the vertical direction.

In some implementations, one contact structure of an intermediate stack of transistors comprises: a conductive via vertically extending in the dielectric stack above the intermediate stack of transistors; a dielectric layer laterally surrounding the conductive via to isolate the contact structure from terminal lines of upper layers transistors above the intermediate stack of transistors; and an enlarged conductive end laterally in electrical contact with a corresponding terminal line of the intermediate stack of transistors.

In some implementations, the semiconductor structure further comprises: a first isolation wall between the first first-type terminal contact region and the first array of transistors to isolate the first common first-type terminal lines from the common second-type terminal lines; and a second isolation wall between the second first-type terminal contact region and the second array of transistors to isolate the second common first-type terminal lines from the common second-type terminal lines.

Another aspect of the present disclosure provides a semiconductor structure, comprising: a plurality of layers of transistors stacked in a vertical direction, each layer of transistors comprising: a first array of transistors sharing a first common first-type terminal line; a second array of transistors sharing a second common first-type terminal line, wherein the first array of transistors and the second array of transistors share a common second-type terminal line; and a plurality of contact structures each coupled with the first common first-type terminal line, the second common first-type terminal line, or the common second-type terminal line; wherein each of the plurality of contact structures electrically coupled with an intermediate stack of transistors penetrates through a dielectric stack above the intermediate stack of transistors.

In some implementations, the transistors are ferroelectric field-effect transistors (FeFET).

In some implementations, each FeFET comprises: a channel layer; a ferroelectric layer having ferroelectricity and encircled by the channel layer in a horizontal plane; and a control gate encircled by the ferroelectric layer in the horizontal plane.

In some implementations, the channel layer comprises a metal oxide semiconductor material.

In some implementations, the channel layer of each FeFET cell has an oval-ring shape in a horizontal plane.

In some implementations, a first portion of the channel layer at a second end of the long diameter of the oval shape is in contact with the first common first-type terminal line or the second common first-type terminal line; and a second portion of the channel layer at a first end of a long diameter of the oval shape is in contact with the common second-type terminal line.

In some implementations, the first common first-type terminal line comprises a first U-shape portion located between adjacent rows of the first array of transistors and with a first opening opposite towards the second array of transistors; the second common first-type terminal line comprises a second U-shape portion located between adjacent rows of the second array of transistors and with a second opening opposite towards the first array of transistors.

In some implementations, the plurality of contact structures comprises: a first common first-type terminal contact structure coupled with the first common first-type terminal line in a first first-type terminal contact region located on a first lateral side of the first array of transistors away from the second array of transistors, a second common first-type terminal contact structure coupled with the second common first-type terminal line in a second first-type terminal contact region located on a second lateral side of the second array of transistors away from the first array of transistors, and a common second-type terminal contact structure coupled with the common second-type terminal line in a common second-type terminal contact region located between the first array of transistors and the second array of transistors.

In some implementations, the first-type terminal is a drain terminal; the second-type terminal is a source terminal; the first common first-type terminal contact structure is connected to a first bit line; the second common first-type terminal contact structure is connected to a second bit line, and the common second-type terminal contact structure is connected to a source line.

In some implementations, each contact structure comprises: a conductive via vertically extending in the dielectric stack above the intermediate stack of transistors; a dielectric layer laterally surrounding the conductive via to isolate the contact structure from terminal lines of upper layers transistors above the intermediate stack of transistors; and an enlarged conductive end laterally in electrical contact with a corresponding terminal line of the intermediate stack of transistors.

In some implementations, the first common first-type terminal lines of the plurality of layers of transistors overlap in the vertical direction; the second common first-type terminal lines of the plurality of layers of transistors overlap in the vertical direction; and the common second-type terminal lines of the plurality of layers of transistors overlap in the vertical direction.

In some implementations, the semiconductor structure further comprises: a first isolation wall between the first first-type terminal contact region and the first array of transistors to isolate the first common first-type terminal lines from the common second-type terminal lines; and a second isolation wall between the second first-type terminal contact region and the second array of transistors to isolate the second common first-type terminal lines from the common second-type terminal lines.

Another aspect of the present disclosure provides a method for forming a semiconductor structure, comprising: forming a dielectric stack including a plurality of first dielectric layers and second dielectric layers alternatively stacked in a vertical direction; forming a plurality of through holes in the dielectric stack; forming a plurality of sacrificial through structures in the plurality of through holes; replacing portions of the second dielectric layers with conductive lines; replacing the plurality of sacrificial through structures with a plurality of transistor structures; and forming a plurality of contact structures each coupled with a corresponding conductive line and penetrating through a remaining portion of the dielectric stack above the corresponding conductive line.

In some implementations, forming the plurality of sacrificial through structures comprises: removing portions of the second dielectric layers exposed by the plurality through holes to form a plurality of recesses on sidewalls of the plurality through holes; and depositing a sacrificial material to fill the plurality of recesses and the plurality through holes.

In some implementations, replacing the plurality of sacrificial through structures with a plurality of transistor structures comprises: removing the plurality of sacrificial through structures from the plurality of recesses and the plurality through holes; forming a plurality of channel layers in the plurality of recesses; forming a ferroelectric layer on a sidewall of each through hole, wherein the ferroelectric layer has ferroelectricity and is laterally encircled by the channel layers; and forming a gate structure in each through hole, wherein the gate structure is laterally encircled by the ferroelectric layer.

In some implementations, the channel layers comprise a metal oxide semiconductor material in direct contact with the conductive layers.

In some implementations, the metal oxide semiconductor material is indium gallium zinc oxide (IGZO).

In some implementations, replacing the portions of second dielectric layers with the conductive lines comprises: forming a plurality of slits penetrating the dielectric stack; removing the portions of the second dielectric layers from the plurality of slits to form a plurality of horizontal openings; forming the conductive lines in the plurality of horizontal openings; and filing the plurality of slits with a dielectric material.

In some implementations, forming the plurality of through holes comprises forming each through hole having an oval shape in a horizontal plane.

In some implementations, the method further comprises: forming isolation walls vertically penetrating the dielectric stack, such that the formed conductive lines in each stack is segmented by the isolation walls to comprise: a first common first-type terminal line shared by a first array of ferroelectric field-effect transistor (FeFET) cells in the layer; a second common first-type terminal line shared by a second array of transistors in the layer; and a common second-type terminal line shared by the first array of transistors and the second array of transistors.

In some implementations, a first portion of the channel layer at a first end of a long diameter of the oval shape is formed in contact with the common second-type terminal line; and a second portion of the channel layer at a second end of the long diameter of the oval shape is formed in contact with the first common first-type terminal line or the second common first-type terminal line.

In some implementations, the first common first-type terminal line is formed to comprise a first U-shape portion located between adjacent rows of the first array of transistors and with a first opening opposite towards the second array of transistors; the second common first-type terminal line is formed to comprise a second U-shape portion located between adjacent rows of the second array of transistors and with a second opening opposite towards the second array of transistors.

In some implementations, forming the plurality of contact structures comprises: forming a first common first-type terminal contact structure coupled with the first common first-type terminal line and located on a first lateral side of the first array of transistors away from the second array of transistors, forming a second common first-type terminal contact structure coupled with the second bit and located on a second lateral side of the second array of transistors away from the first array of transistors, and forming a common second-type terminal contact structure coupled with the common second-type terminal line and located between the first array of transistors and the second array of transistors.

In some implementations, forming one the plurality of contact structures comprises: forming a contact hole penetrating through an upper portion of the remaining portion of the dielectric stack and stopping at one second dielectric layer at a same level of the one corresponding conductive line; forming a dielectric filling structure to fill the contact hole; performing a punch etching to remove a portion of the dielectric filling structure to expose a portion of the one second dielectric layer adjacent to the one corresponding conductive line; removing the portion of the one second dielectric layer to expose the one corresponding conductive line; and depositing a conductive material in the contact hole to form the one contact structure, such that the contact structure is isolated the from the conductive lines above the one corresponding conductive line, and in electrical contact with the one corresponding conductive line in a lateral direction.

In some implementations, the first common first-type terminal lines in the plurality of layers of conductive lines are formed overlap in the vertical direction; the second common first-type terminal lines in the plurality of layers of conductive lines are formed overlap in the vertical direction; and the common second-type terminal lines in the plurality of layers of conductive lines are formed overlap in the vertical direction.

Other aspects of the present disclosure can be understood by those skilled in the art in light of the description, the claims, and the drawings of the present disclosure.

### BRIEF DESCRIPTION OF THE DRAWINGS

The accompanying drawings, which are incorporated herein and form a part of the specification, illustrate implementations of the present disclosure and, together with the description, further serve to explain the principles of the present disclosure and to enable a person skilled in the pertinent art to make and use the present disclosure.

FIG. 1 illustrates a schematic cross-section of a FeFET, according to some implementations of the present disclosure.

FIG. 2 illustrates charge distribution in the memory film of a 3D FeFET RAM cell during erasing and programing operations, in accordance with some implementations of the present disclosure.

FIG. 3 illustrates a schematic top view of 3D FeFET, in accordance with some implementations of the present disclosure.

FIG. 4 illustrates a schematic top view of a pattern design of a 3D memory array structure, in accordance with some implementations of the present disclosure.

FIG. 5 illustrates a schematic circuit diagram of the pattern design of the 3D memory array structure as shown in FIG. 4, in accordance with some implementations of the present disclosure.

FIGS. 6A-6C illustrate schematic top views of a pattern design of a 3D memory structure, in accordance with some implementations of the present disclosure.

FIG. 7 illustrates a schematic circuit diagram of another pattern design of a 3D memory array structure as shown in FIGS. 6A-6C, in accordance with some other implementations of the present disclosure.

FIG. 8 illustrates a flow diagram of a method for forming a 3D memory structure, according to some implementations of the present disclosure.

FIG. 9A illustrates a schematic cross-sectional side view of a 3D memory structure at certain fabricating stage of the method shown in FIG. 8 according to some implementations of the present disclosure.

FIG. 9B illustrates a schematic top view of the 3D memory structure at certain fabricating stages of the method shown in FIG. 8 according to some implementations of the present disclosure.

FIG. 10 illustrates a schematic cross-sectional side view of a 3D memory structure at certain fabricating stage of the method shown in FIG. 8 according to some implementations of the present disclosure.

FIG. 11A illustrates a schematic cross-sectional side view of a 3D memory structure at certain fabricating stage of the method shown in FIG. 8 according to some implementations of the present disclosure.

FIG. 11B illustrates a schematic top view of the 3D memory structure at certain fabricating stages of the method shown in FIG. 8 according to some implementations of the present disclosure.

FIG. 12A illustrates a schematic cross-sectional side view of a 3D memory structure at certain fabricating stage of the method shown in FIG. 8 according to some implementations of the present disclosure.

FIG. 12B illustrates a schematic top view of the 3D memory structure at certain fabricating stages of the method shown in FIG. 8 according to some implementations of the present disclosure.

FIG. 13A illustrates a schematic cross-sectional side view of a 3D memory structure at certain fabricating stage of the method shown in FIG. 8 according to some implementations of the present disclosure.

FIG. 13B illustrates a schematic top view of the 3D memory structure at certain fabricating stages of the method shown in FIG. 8 according to some implementations of the present disclosure.

FIG. 14A illustrates a schematic cross-sectional side view of a 3D memory structure at certain fabricating stage of the method shown in FIG. 8 according to some implementations of the present disclosure.

FIG. 14B illustrates a schematic top view of the 3D memory structure at certain fabricating stages of the method shown in FIG. 8 according to some implementations of the present disclosure.

FIG. 15A illustrates a schematic cross-sectional side view of a 3D memory structure at certain fabricating stage of the method shown in FIG. 8 according to some implementations of the present disclosure.

FIG. 15B illustrates a schematic top view of the 3D memory structure at certain fabricating stages of the method shown in FIG. 8 according to some implementations of the present disclosure.

FIG. 16A illustrates a schematic cross-sectional side view of a 3D memory structure at certain fabricating stage of the method shown in FIG. 8 according to some implementations of the present disclosure.

FIG. 16B illustrates a schematic top view of the 3D memory structure at certain fabricating stages of the method shown in FIG. 8 according to some implementations of the present disclosure.

FIG. 17A illustrates a schematic cross-sectional side view of a 3D memory structure at certain fabricating stage of the method shown in FIG. 8 according to some implementations of the present disclosure.

FIG. 17B illustrates a schematic top view of the 3D memory structure at certain fabricating stages of the method shown in FIG. 8 according to some implementations of the present disclosure.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements. The drawing in which an element first appears is indicated by the leftmost digit(s) in the corresponding reference number.

Implementations of the present disclosure will be described with reference to the accompanying drawings.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one implementation,” “an implementation,” “an example implementation,” “some implementations,” etc., indicate that the implementation described can include a particular feature, structure, or characteristic, but every implementation can not necessarily include the particular feature, structure, or characteristic. Moreover, such phrases do not necessarily refer to the same implementation. Further, when a particular feature, structure or characteristic is described in connection with an implementation, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer there between. Moreover, “above” or “over” not only means “above” or “over” something, but can also include the meaning it is “above” or “over” something with no intermediate feature or layer there between (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, there above, and/or there below. A layer can include multiple layers. For example, an interconnect layer can include one or more conductive and contact layers (in which contacts, interconnect lines, and/or vertical interconnect accesses (VIAs) are formed) and one or more dielectric layers.

In the present disclosure, for ease of description, “tier” is used to refer to elements of substantially the same height along the vertical direction. For example, a word line and the underlying gate dielectric layer can be referred to as “a tier,” a word line and the underlying insulating layer can together be referred to as “a tier,” word lines of substantially the same height can be referred to as “a tier of word lines” or similar, and so on.

As used herein, the term “nominal/nominally” refers to a desired, or target, value of a characteristic or parameter for a component or a process step, set during the design phase of a product or a process, together with a range of values above and/or below the desired value. The range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., +10%, +20%, or +30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings”) on a laterally-oriented substrate so that the memory strings extend in the vertical direction with respect to the substrate.

In a 3D NAND memory, memory cells can be programmed for data storage based on charge-trapping technology. The storage information of a memory cell depends on the amount of charge trapped in a storage layer. Although 3D NAND memory can be high density and cost-effective, it suffers from low write speed and high-power consumption at system level due to required periphery (e.g., charge pumps). On the other hand, phase change memory generally has large leakage current and high power consumption. Therefore, a need exists to develop a new high-speed and high-density storage class memory (SCM).

Ferroelectric Field Effect Transistor (FeFET) Random Access Memory (RAM) is a high performance and low-power non-volatile memory that can combines the benefits of conventional non-volatile memories (e.g., Flash and EEPROM) and high-speed RAM (e.g., SRAM and DRAM.) FeFET RAM can outperform existing memories like EEPROM and Flash with less power consumption, faster response, and greater endurance to multiple read-and-write operations. The traditional planar FeFET RAM is difficult to scale down. By replacing the charge trapping storage layer in a 3D NAND flash memory with a ferroelectric material (e.g., Si:HfO₂), a FeFET RAM with a similar 3D NAND architecture can realize scalable dimensions without performance penalty. However, due to the small size of the source and drain contacts in the existing 3D FeFET RAM architecture, it is difficult to lead the source and drain separately to realize individual access of each memory cell. Therefore, it is desired to develop a new 3D architecture of FeFET RAM.

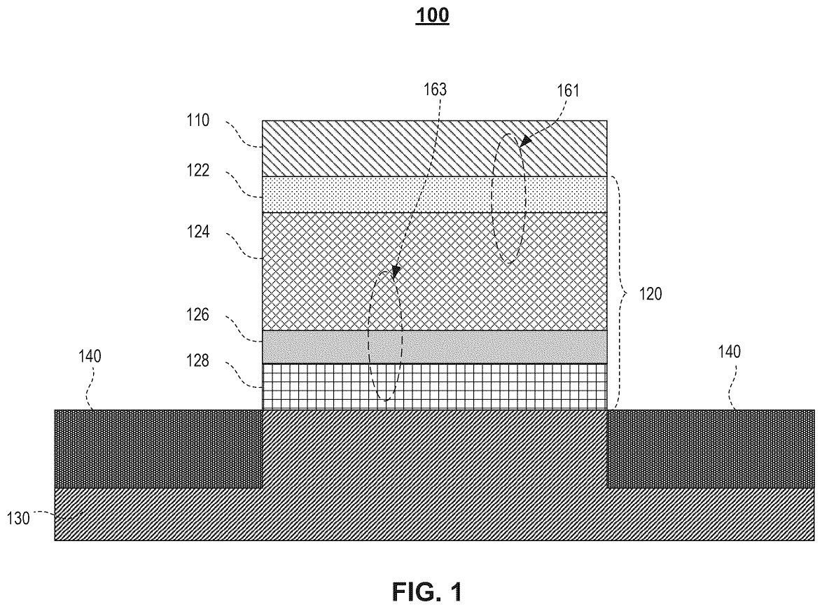

FIG. 1 illustrates a schematic cross-section of a FeFET 100, according to some implementations of the present disclosure. The FeFET 100 can include a control gate 110, a memory film 120, a channel layer 130, and source/drain electrodes 140.

In the FeFET 100, memory film 120 can be located between the control gate 110 and the channel layer 130, and can include a barrier layer 122, a ferroelectric layer 124, and an electrode layer 126, and an interface layer 128. In some implementations, barrier layer 122 is located between the control gate 110 and the ferroelectric layer 124. The control gate 110 can be a metal layer or a polycrystalline silicon layer. The barrier layer 122 can be used to block the interactions between the ferroelectric layer 124 and the control gate 110. The barrier layer 122 can have a thickness in a range between about 5 nm and about 50 nm. The barrier layer can include titanium nitride (TiN), silicon oxide (SiO₂), silicon nitride (Si₃N₄), silicon oxynitride (Si₂O₂N), high-k dielectric materials (e.g., HfO₂, Al₂O₃), and/or any combination thereof. The barrier layer 122 can be formed by any suitable physical vapor deposition (PVD) or chemical vapor deposition (CVD).

In some implementations, the ferroelectric layer 124 can include a metal oxide semiconductor material, such as indium gallium zinc oxide (IGZO). In some implementations, the ferroelectric layer 124 can include a high-k (i.e., high dielectric constant) dielectric material, which can include transitional metal oxides such as hafnium-zirconium oxide (HZO), hafnium oxide (HfO₂), aluminum oxide (Al₂O₃), Zirconium oxide (ZrO₂), titanium oxide (TiO₂), niobium oxide (Nb₂O₅), tantalum oxide (Ta₂O₅), tungsten oxide (WO₃), molybdenum oxide (MO₃), vanadium oxide (V₂O₃), lanthanum oxide (La₂O₃), and/or any combination thereof. In some implementations, to improve the ferroelectric property, the high-k dielectric material can be doped. For example, the ferroelectric layer 124 can be HZO or HfO₂ doped with silicon (Si), (Yttrium) Y, Gadolinium (Gd), Lanthanum (La), Zirconium (Zr) or Aluminum (Al), or any combination thereof. In some implementations, the ferroelectric layer 124 can include Zirconate Titanate (PZT), Strontium Bismuth Tantalate (SrBi₂Ta₂O₉), Barium Titanate (BaTiO₃), PbTiO₃, and BLT ((Bi,La)₄Ti₃O₁₂), or any combination thereof.

In some implementations, the ferroelectric layer 124 can be disposed by chemical vapor deposition (CVD), for example, metal organic chemical vapor deposition (MOCVD), low pressure chemical vapor deposition (LPCVD), plasma enhanced chemical vapor deposition (PECVD), high-density plasma chemical vapor deposition (HDP-CVD), etc. The ferroelectric layer 124 can also be disposed by atomic layer deposition (ALD), sputtering, evaporating, or any combination thereof. In some implementations, the ferroelectric layer 124 can have a thickness in a range between 5 nm and 100 nm.

In some implementations, the interface layer 128 can be located between the ferroelectric layer 124 and the channel layer 130. The interface layer 128 can be used to reduce the possibility of material intermixing between the ferroelectric layer 124 and the channel layer 130. In this example, the effective gate dielectric of the FeFET is the combination of the ferroelectric layer 124 and the interface layer 128. A thinner effective gate dielectric can provide better control of the channel layer 130 from the control gate 110. Thus, the thickness of the interface layer 128 can be in a range between about 5 nm and about 50 nm. In some implementation, the interface layer 128 can be silicon oxide, silicon nitride, silicon oxynitride, high-k dielectric material (e.g., HfO₂, HfAlO, Al₂O₃), and/or any combination thereof. The interface layer 128 can be formed by any suitable film deposition technique such as ALD, CVD, sputtering, evaporation, and/or any combination thereof. The interface layer 128 can also be formed by oxidation, nitridation, and/or a combination thereof.

In some implementations, the memory film 120 can further include an electrode layer 126 between the ferroelectric layer 124 and the interface layer 128. As such, the control gate 110, the ferroelectric layer 124, and the electrode layer 126 forms a metal-insulator-metal (MIM) capacitor 161 that is in series with a floating gate transistor (FG-MOSFET) 163 where the electrode layer 126 functions as a floating gate and the interface layer 128 functions as a gate dielectric.

In some implementations, channel layer 130 can include amorphous silicon, polycrystalline silicon, monocrystalline silicon, and/or any combination thereof. The channel layer 130 can be formed by any suitable thin film deposition technique such as ALD, CVD, sputtering, etc. In some implementations, portions of channel layer 130 can be doped to form the source/drain electrode 140 on each side of the channel layer 130 respectively. In some other implementations, the source/drain electrode 140 can be metal layers formed on the channel layer 130.

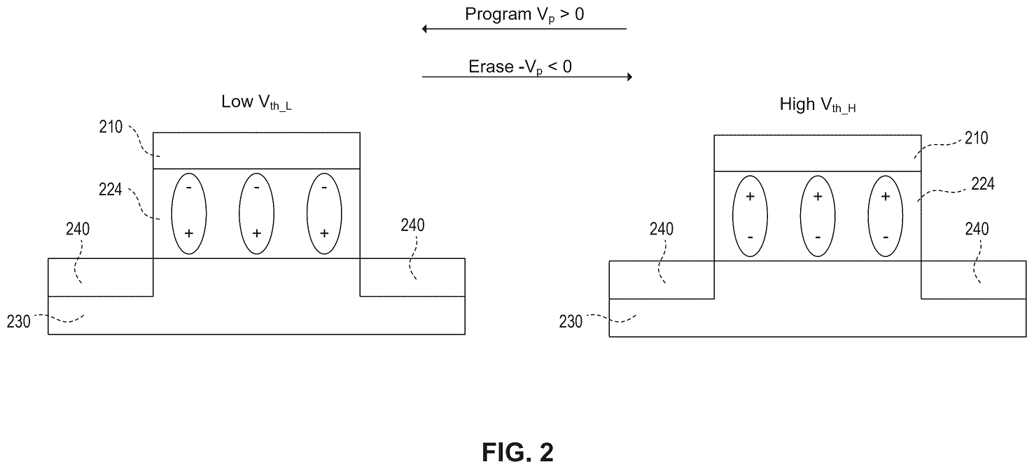

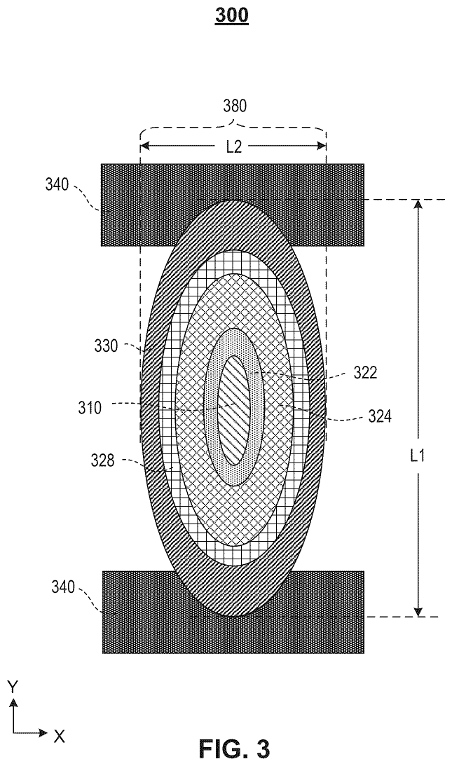

Referring to FIG. 2, charge distribution in the memory film of a FeFET during erasing and programing operations are illustrated in accordance with some implementations of the present disclosure. It is noted that, the barrier layer 222, the electrode layer 226, and the interface layer 228 of the FeFET are omitted in FIG. 3 for simplicity.

During a programing operation as shown in the left figure of FIG. 2, the programming voltage Vₚ applied on the control gate 210 provides a positive voltage across the ferroelectric film 224 that is larger than the coercive voltage (Vₚ>V_{c}), the ferroelectric film 224 can have the positive remnant polarization Pᵣ, with a direction pointing from the control gate 210 to the channel layer 230. As a result, top surface charges near the control gate 210 are negative and bottom surface charges near the channel layer 230 are positive. The positive bottom surface charges near channel layer 230 can lower the threshold voltage Vₜₕ of the transistor. Therefore, a corresponding capacitor control by the FeFET can be programmed to a low threshold voltage V_{th_L}, and set to a logic state of “1.”

During an erasing operation as shown in the right figure of FIG. 2, the erase voltage-Vₚ (e.g., negative voltage) is applied on the control gate 210 with a magnitude larger than the reversed coercive voltage (i.e., |−Vₚ|>|−V_{c}|), the ferroelectric film 224 can be negatively polarized to have the reversed remnant polarization −Pᵣ, with a direction pointing from the channel layer 230 to the control gate 210. The top surface charges near the control gate 210 are positive and bottom surface charges near the channel layer 230 are negative. The negative bottom surface charges near the channel increase the threshold voltage Vₜₕ of the transistor. Therefore, the corresponding capacitor control by the FeFET can be programmed to a high threshold voltage V_{th_H}, and reset to a logic state of “0.”

It is noted that the coercive field E_{c}, the coercive voltage V_{c}, the programming voltage Vₚ and the remnant polarization Pᵣ are not necessarily symmetric around zero. Positive and negative values can have different magnitudes. To simplify the discussion below, it is assumed that the magnitudes are the same in the reversed direction. A person of ordinary skill in the art should be able to apply the methods below for general conditions.

As discussed above, by applying suitable voltage pulses on the control gate 210, polarization direction of the ferroelectric film 224 can be switched and threshold voltage of the FeFET can be changed, which impact the conductance of the channel layer 230 and the on/off state of the FeFET. The logic states (or the storage data) of the corresponding capacitor control by the FeFET can be determined accordingly.

In some implementations, during a reading operation (not shown in FIG. 2), by applying a reading voltage V_{read} on the control gate 210, the conductance of the channel layer 230 can be measured from the source/drain electrodes 240 of the FeFET. The logic state or the threshold voltage of the corresponding DRAM memory cell including the FeFET the corresponding capacitor control by the FeFET can be verified. Compared with a traditional NAND cell being operated based on charge trapping in the memory film, the FeFET RAM cell can be controlled by polarization in the ferroelectric film 224 instead.

It is noted that, the electrode layer 126 shown in FIG. 1 is optional. During an operation of the FeFET, the voltage of the electrode layer 126 is determined by the number of bottom surface charges of the ferroelectric film 124/224. By switching the polarization direction in the ferroelectric layer 124/224, the number of bottom surface charges can be changed, and the voltage of the electrode layer 126 can be changed accordingly. Thus, the threshold voltage of the FeFET can be changed. The electrode layer 126 in the FeFET can provide similar functions as a floating gate in a traditional NAND memory cell, except that the voltage of the electrode layer 126 is controlled by the polarization of the ferroelectric layer 124/224. The applied voltage on control gate 110/210 is divided between the MIM capacitor 161 and the FG-MOSFET 163. As a result, relatively larger voltage is necessary to switch the polarization of the ferroelectric layer 124/224. To reduce writing voltage, a thinner ferroelectric layer 124/224 can be used in some implementations. The MIM capacitor 161 can have larger capacitor from scaling the thickness of the ferroelectric layer 124/224 such that a larger portion of the applied voltage can be dropped across the MIM capacitor 161.

Referring to FIG. 3, a schematic top view of a 3D FeFET is illustrated in accordance with some implementations of the present disclosure. The 3D FeFET 300 can include a control gate 310, a barrier layer 322, a ferroelectric film 324, an interface layer 328, a channel layer 330, and source/drain electrodes 340. It is noted that, the source electrode and the drain electrode 340 are separated by an insulating layer that is omitted in for simplicity. Channel layer 330 can be in physical contact with the source/drain electrodes 340, and can surround the interface layer 328 in the cross-sectional X-Y plane. The interface layer 328 can surround the ferroelectric film 324 in the cross-sectional X-Y plane. The ferroelectric film 324 can surround the barrier layer 322 in the cross-sectional X-Y plane. The barrier layer 322 can surround control gate 310 in the cross-sectional X-Y plane.

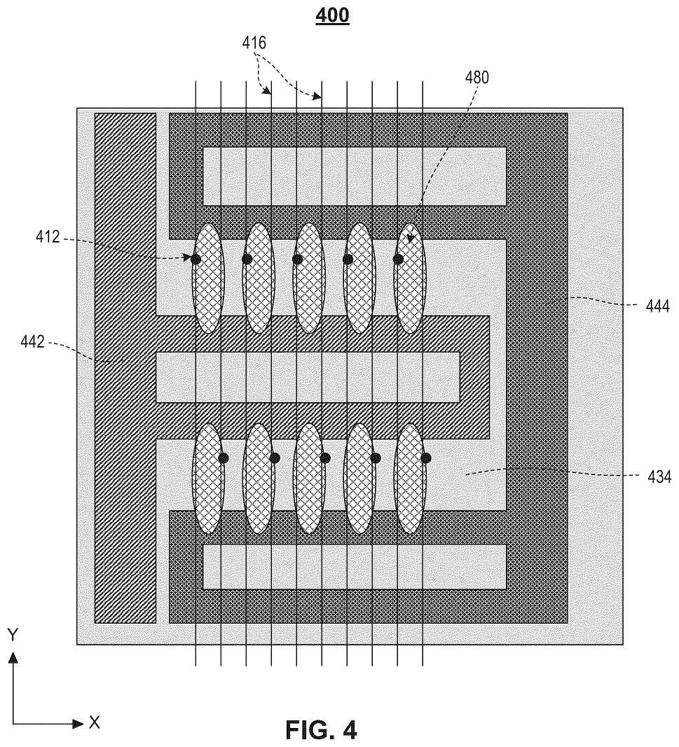

In some implementations, control gate 310, barrier layer 322, ferroelectric film 324, interface layer 328, and channel layer 330 can form a through structure 380 located in a through hole extending along a vertical direction perpendicular to the horizontal X-Y plane. The cross section of the through hole in the horizontal X-Y plane can be an oval shape shown in FIG. 4. In some implementations, a ratio between a long diameter L1 of the through structure 380 and a short diameter L2 of the through structure 380 is larger than 1. In some implementations, the long diameter L1, the short diameter L2, and the ratio L1/L2 can be determined based on a total number of 3D FeFET RAM cells in each memory string in the vertical direction. For example, the sizes of the long diameter L1 and the short diameter L2, and the ratio L1/L2 can be increased when total number of 3D FeFET RAM cells in each memory string is increased. In some implementations, the long diameter L1 of the through structure 380 can provide an increased contacting area and/or multiple contacting area options for landing a control gate contact. As such, the gate control ability of the 3D memory device can be enhanced.

Referring to FIG. 4, a schematic top view of a pattern design of a 3D memory array structure 400 is illustrated in accordance with some implementations of the present disclosure. In the X-Y plane, the 3D memory array structure 400 can include a plurality of through structures 480 arranged in an array form. The plurality of through structures 480 can each have an oval shape in the cross section in the horizontal X-Y plane, similar to the showing of FIG. 3. The short diameter of each through structure 480 can be along a first lateral direction (e.g., X-direction), and the long diameter of each through structure 480 can be along a second lateral direction (e.g., Y-direction). The array of through structures 480 can share a common source line 442 and a common bit line 444. It is noted that in FIG. 4, for illustrative purposes, five through structures 480 are shown in each row for simplicity. In some implementations, the number “n” of the through structures 480 in each row can be larger than five to increase storage capacity.

As shown in FIG. 4, the source line 442 and the bit line 444 can each include a trunk line (also referred as “common source trunk line” and “common bit trunk line”) extending along the Y-direction and located on each side of the array of the through structures 480 respectively, and also can each include a plurality of branch lines (also referred as “common source branch lines” and “common bit branch lines”) located between adjacent rows of the through structures 480 in an alternatively interlaced manner. In some implementations, each branch line of the source line 442 or the bit line 444 can have a U-shape portion or a single strip shape and extend along the X-direction. That is, the source line 442 and the bit line 444 can each have a comb shape and can be positioned in a face-to face manner with the single-strip teeth alternatively interlaced with each other. The source line 442 and the bit line 444 are separated by insulating layer 434.

Each row of through structures 480 are arranged between adjacent branch lines of the source line 442 and the bit line 444. That is, there are one common source branch line and one common bit branch line between adjacent rows of the through structures 480. The lower ends of the plurality of through structures 480 in each row can be commonly in contact with one branch line of the source line 442, and the upper ends of the plurality of through structures 480 in each row can be commonly in contact with one adjacent branch line of the source line 442. As such, the channel layers (e.g., the channel layer 330 as shown in FIG. 3) of the plurality of through structures 480 in a same row can be in physical contact with the common source line 442 and the common bit line 444.

Further, as shown in FIG. 4, the 3D memory array structure 400 can include a plurality of gate lines 416 (also referred as “word lines”) arranged parallel with each other and extending along the second lateral direction (e.g., Y-direction). Since there are two rows of through structures 480 in each finger, two gate lines 416 can be arranged for each column of two through structures 480, wherein one gate line 416 can be connected to the control gate (e.g., control gate 310 as shown in FIG. 3) of the through structure 480 in the first row via a first control gate contact 412, and the other gate line 416 can be connected to the control gate of the through structure 480 in the second row via a second control gate contact 414. As discussed above in connection with FIG. 3, the oval shape of the through structure 480 in the X-Y plane can provide an increased contacting area and/or multiple contacting area options for landing the first control gate contact 412 or the second control gate contact 414.

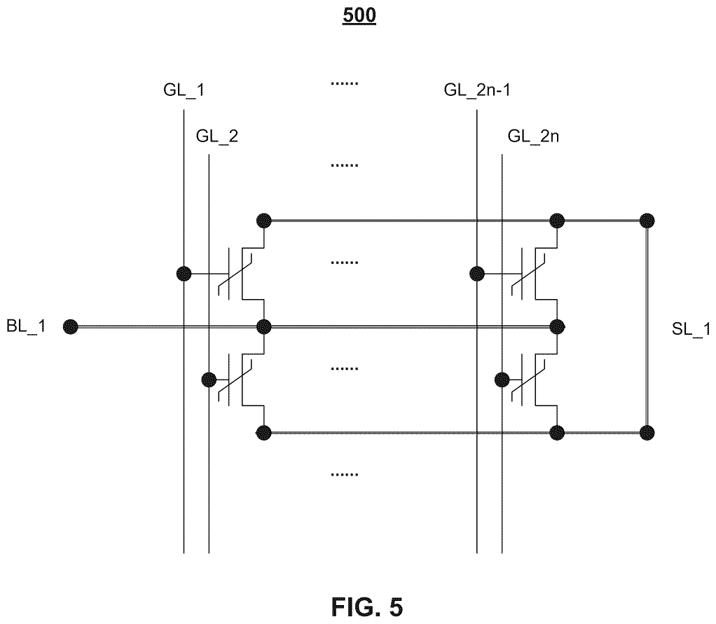

FIG. 5 illustrates a schematic circuit diagram of the pattern design of the 3D memory array structure 400 as shown in FIG. 4. It is noted that, the schematic circuit diagram 500 corresponds to one layer of 3D FeFET RAM cells in the 3D memory array structure in the X-Y plane. As shown in FIG. 5, each row of FeFETs includes a number “n” of FeFETs. The array of FeFETs share a common source line SL_1, and share a common bit line BL_1. A number “2n” of gate lines GL_1, . . . , GL_2n can each be connected to a corresponding FeFET, such that the number “2n” of FeFETs can be independently controlled. Therefore, each memory cell of the 3D memory array structure 500 can be randomly accessed.

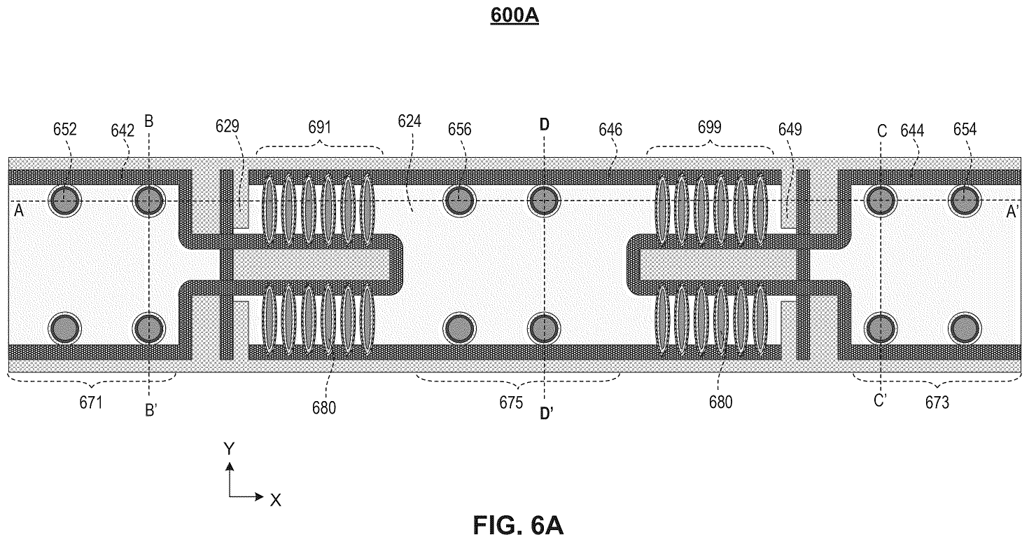

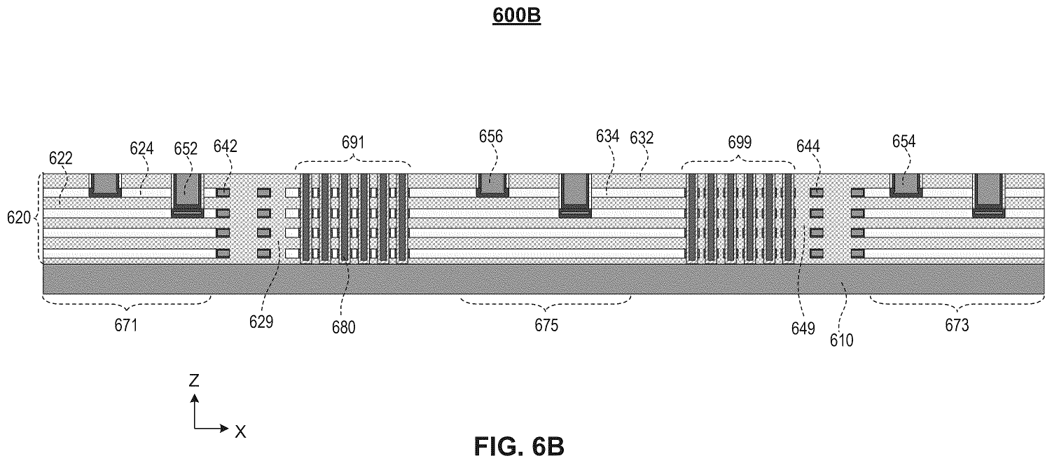

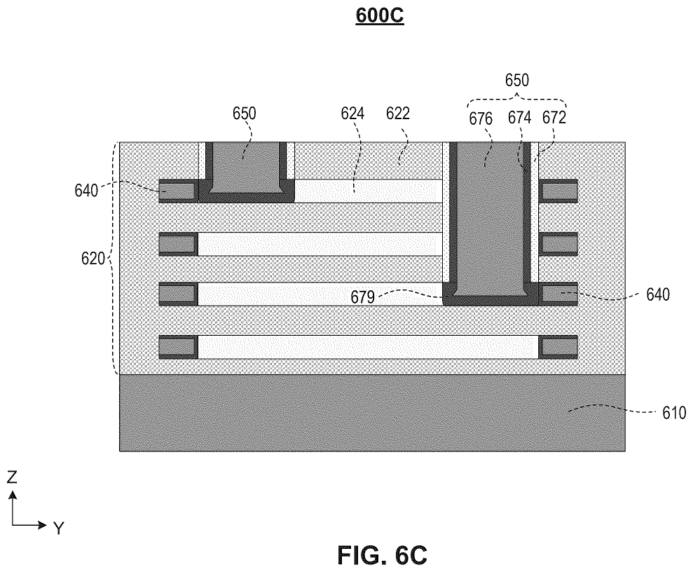

Referring to FIG. 6A, a schematic top view 600A of a pattern design of a 3D memory structure is illustrated in accordance with some implementations of the present disclosure. Referring to FIG. 6B, a schematic cross-sectional side view 600B of the 3D memory structure shown in FIG. 6A along AA′ line is illustrated in accordance with some implementations of the present disclosure. Referring to FIG. 6C, a cross-sectional side view 600C of the 3D memory structure shown in FIG. 6A along the BB′ line, or the CC′ line, or the DD′ line is illustrated in accordance with some implementations of the present disclosure.

As shown in FIG. 6B, the 3D memory array structure includes a substrate 610 and a film stack 620 on the substrate 620. In some implementations, the substrate 620 can be any suitable semiconductor substrate having any suitable structure, such as a monocrystalline single-layer substrate, a polycrystalline silicon (polysilicon) single-layer substrate, a polysilicon and metal multi-layer substrate, etc. In the vertical direction (i.e., Z-direction) perpendicular to the top surface of the substrate 610, the film stack 620 can include alternative stacked first dielectric layers 622 and second dielectric layers 624. As shown in FIGS. 6A-6C, plurality of conductive lines 640 (including 642, 644, 646) can be located on same levels of the second dielectric layers 624. The conductive lines 640 and the second dielectric layers 624 are sandwiched between adjacent first dielectric layers 622.

In the first lateral direction (i.e., X-direction), the 3D memory array structure includes a first contact region 671 on a first lateral side of the 3D memory array structure, a second contact region 673 on a second lateral side of the 3D memory array structure, and a third contact region 675 in the middle of the 3D memory array structure. The 3D memory array structure further includes a first array of transistors 691 between the first contact region 671 and the third contact region 675, and a second array of transistors 699 between the second contact region 673 and the third contact region 675.

In the vertical direction (i.e., Z-direction), the first array of transistors 691 and the second array of transistors 699 include a plurality of memory strings formed in a plurality of through holes each extending through film stack 620. The through hole can be formed by removing portions of the first dielectric layer 622 and the second dielectric layers 624, and the conductive lines 640, such that inner sidewalls of the first dielectric layers 622, the second dielectric layers 644, and the conductive lines 640 are exposed by the through hole. A through structure 680 can be formed in each through hole. In some implementations, the through structure 680 can include a channel layer on the sidewall of the through hole, a memory film on the sidewall of the channel layer, and a core control gate surrounded by the memory film. As such, the through structure 680 and the plurality of conductive lines 640 in the film stack 620 can form a column of 3D FeFETs stacked in the vertical direction (Z-direction).

As shown in FIG. 6A, each layer of FeFETs in the lateral X-Y plane can comprises a first array of transistors 691 sharing a first common first-type terminal line 642 extending into the first contact region 671, a second array of transistors 699 sharing a second common first-type terminal line 644 extending into the second contact region 673. The first array of transistors 691 and the second array of transistors 699 can share a common second-type terminal line 646 extending into the third contact region 675. In some implementations, a first portion of the channel layer at a second end of the long diameter of the oval shape through structure 680 is in contact with the first common first-type terminal line 642 or the second common first-type terminal line 644. A second portion of the channel layer at a first end of a long diameter of the oval shape through structure 680 is in contact with the common second-type terminal line 646. The second-type terminal can be a source terminal, thus the common second-type terminal line can serve as a common source line of each row of transistors, as shown in FIG. 6A.

In some implementations, the first common first-type terminal line 642 comprises a first U-shape portion located between adjacent rows of the first array of transistors 691 and with a first opening opposite towards the second array of transistors 699. The second common first-type terminal line 644 comprises a second U-shape portion located between adjacent rows of the second array of transistors 699 and with a second opening opposite towards the first array of transistors 691. In some implementations, the first-type terminal can be a drain terminal, thus the first common first-type terminal line 642 can serve as a common drain line of the first array of transistors 691, and the second common first-type terminal line 644 can serve as a common drain line of the second array of transistors 699.

As shown in FIG. 6B, the first common first-type terminal lines 642 of the plurality of layers of transistors overlap in the vertical direction, and the second common first-type terminal lines 644 of the plurality of layers of transistors overlap in the vertical direction. Although not shown, the common second-type terminal lines 646 of the plurality of layers of transistors overlap in the vertical direction.

As shown in FIGS. 6A-6C, the 3D memory array structure includes a plurality of contact structures 650 (including 652, 654, 656). The first common first-type terminal contact structures 652 can be coupled with the first common first-type terminal lines 642 and located in the first first-type terminal contact region 671 at a first lateral side of the first array of transistors 691 away from the second array of transistors 699. The second common first-type terminal contact structures 654 can be coupled with the second common first-type terminal lines 644 and located in the second first-type terminal contact region 673 at a second lateral side of the second array of transistors 699 away from the first array of transistors 691. The common second-type terminal contact structures 656 can be coupled with the common second-type terminal lines 646 and located in the common second-type terminal contact region 675 between the first array of transistors 691 and the second array of transistors 699.

In some implementations, each first common first-type terminal contact structure 652 couple with a corresponding first common first-type terminal line 642 can be connected between a first bit line (not shown) and the drain terminals of the first array of transistors 691 in the same layer of the corresponding first common first-type terminal line 642. Each second common first-type terminal contact structure 654 couple with a corresponding second common first-type terminal line 644 can be connected between a second bit line (not shown) and the drain terminals of the second array of transistors 699 in the same layer of the corresponding second common first-type terminal line 644. Each common second-type terminal contact structure 656 couple with a corresponding common second-type terminal line 646 can be connected between a source line (not shown) and the source terminals of a row of transistors in the same layer of the corresponding second common first-type terminal line 646.

As shown in FIG. 6C, contact structure 650 can comprise a conductive via vertically extending in the dielectric stack 620. The conductive via can include a conductive layer 674 on the sidewall and bottom surface of a contact hole and a conductive filling structure 676 filling the in the contact hole. The conductive via can further include an enlarged conductive end 679 laterally in electrical contact with a corresponding terminal line 640. The contact structure 650 can further include a spacer layer 672 laterally surrounding the conductive via to isolate the conductive via from other terminal lines 640.

In some implementations, as shown in FIGS. 6A-6B, the 3D memory array structure includes further comprises a first isolation wall 629 between the first first-type terminal contact region 671 and the first array of transistors 691 to isolate the first common first-type terminal lines 642 from the common second-type terminal lines 646. The 3D memory array structure includes further comprises a second isolation wall 649 between the second first-type terminal contact region 673 and the second array of transistors 699 to isolate the second common first-type terminal lines 644 from the common second-type terminal lines 646.

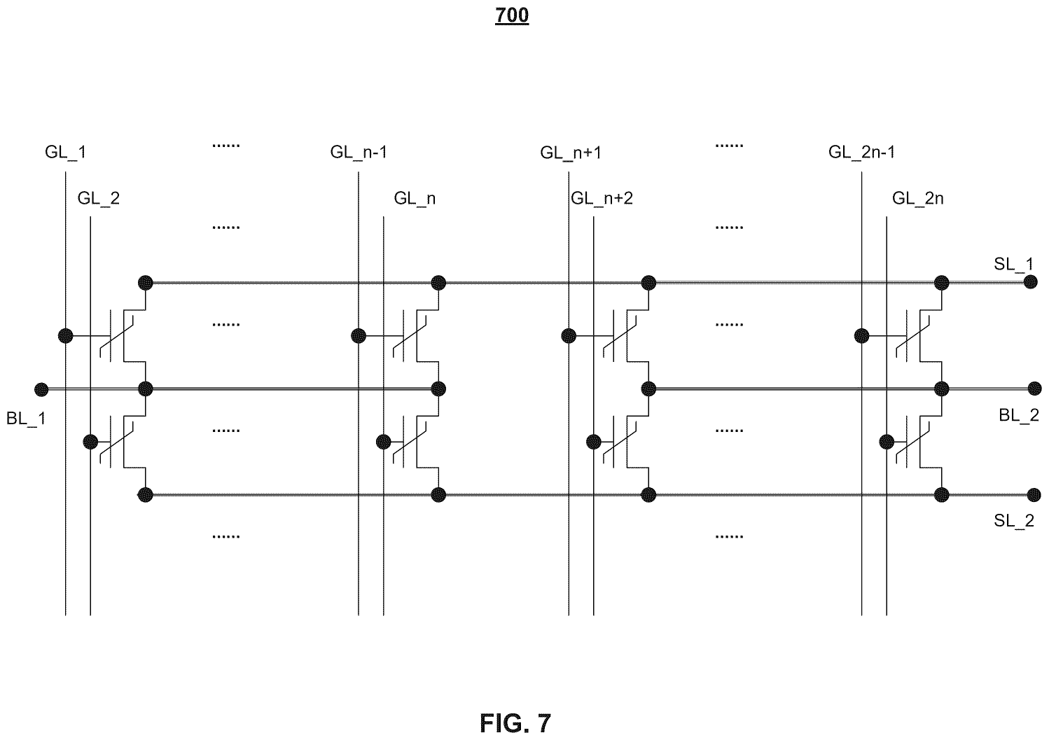

FIG. 7 illustrates a schematic circuit diagram 700 of the 3D memory array structure according to the pattern design as shown in FIGS. 6A-6C. It is noted that, the schematic circuit diagram 700 corresponds to one layer of 3D FeFETs of the 3D memory array structure in the X-Y plane. As shown in FIG. 7, a first row of FeFETs share a first common source line SL_1, and a second row of FeFETs share a second common source line SL_2. The left array of FeFETs shares a first common bit line BL_1, and the right array of FeFETs shares a second common bit line BL_2. A number “2n” of gate lines GL_1, . . . , GL_2n can each be connected to a corresponding FeFET, such that the number “2n” of FeFETs in the two adjacent rows can be independently controlled. Therefore, each FeFET in the 3D memory array structure can be randomly accessed.

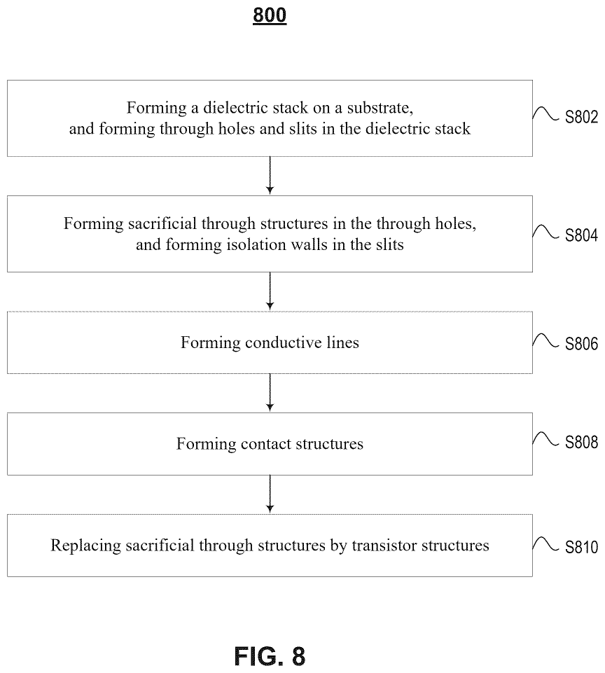

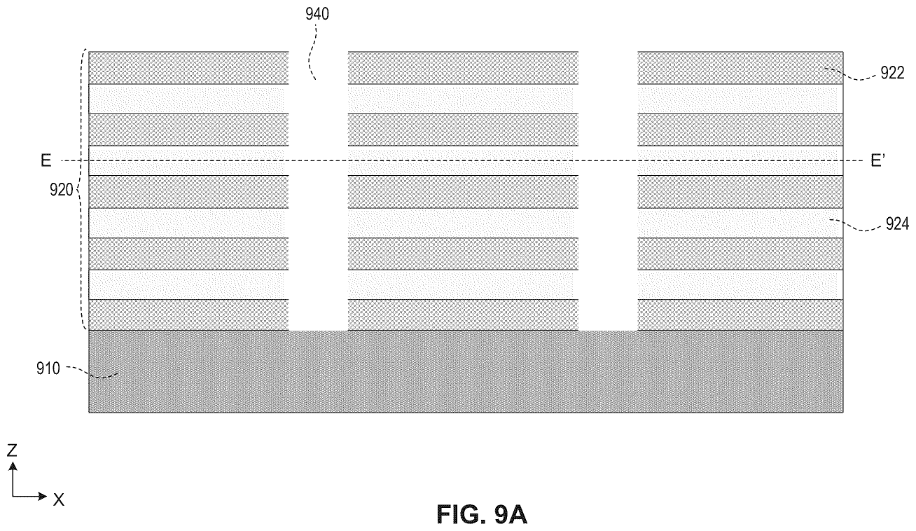

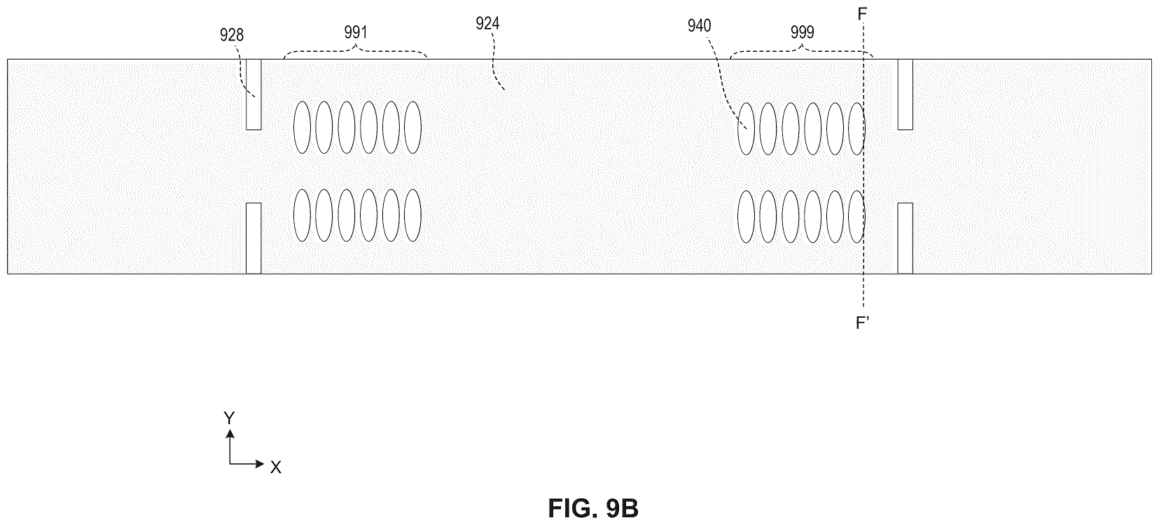

FIG. 8 illustrates a flow diagram of a method 800 for forming a 3D memory structure, according to some implementations of the present disclosure. FIGS. 9A-9B, 10, 11A-11B, 12A-12B, 13A-13B, 14A-14B, 15A-15B, 16A-16B, and 17A-17B illustrate schematic cross-sectional views and/or top views of the 3D memory structure at certain fabricating stages of the method 800 shown in FIG. 8 according to some implementations of the present disclosure. It is understood that the operations shown in method 800 are not exhaustive and that other operations can be performed as well before, after, or between any of the illustrated operations. Further, some of the operations may be performed simultaneously, or in a different order than shown in FIG. 8.

As shown in FIG. 8, method 800 starts at operation 802, in which a dielectric stack can be formed on a substrate, and a plurality of through holes and slits can be formed in the dielectric stack. FIG. 9A illustrates a schematic cross-sectional view of the 3D memory structure after operation 802 along the FF′ line of FIG. 9B, according to some implementations of the present disclosure. FIG. 9B illustrates a schematic top view of the 3D memory structure after operation 802 along the EE′ line of 9A, according to some implementations of the present disclosure.

In some implementations, the substrate 910 can be any suitable semiconductor substrate having any suitable structure, such as a monocrystalline single-layer substrate, a polycrystalline silicon (polysilicon) single-layer substrate, a polysilicon and metal multi-layer substrate, etc. In such implementations, the dielectric stack 920 can be formed directly on the semiconductor substrate 910. In some other implementations, the substrate 910 can be a carrier substrate, which can include any suitable semiconductor materials, or an electrically non-conductive material, such as a glass, a plastic, or a sapphire wafer. In such implementations, the dielectric stack 920 can be formed directly on a temporary substrate, and a flipping over processing will be performed in a subsequent operation, the carrier substrate 910 can be formed in the dielectric stack 920, and the temporary substrate can then be removed.

In accordance with some implementations, as shown in FIG. 9A, the dielectric stack 920 including a plurality of dielectric layer pairs can be formed on substrate 910. Each dielectric layer pairs of the dielectric stack 920 can include an alternating stack of a first dielectric layer 922 and a second dielectric layer 924 that is different from first dielectric layer 922. In some implementations, the first dielectric layers 922 and portions of the second dielectric layer 924 can be used as insulating layers, and other portions of the second dielectric layer 924 can be used as sacrificial layers which are to be removed in the subsequent processes.

The plurality of first dielectric layers 922 and second dielectric layers 924 are extended in a lateral direction that is parallel to a surface of the substrate 910. In some implementations, there are more layers than the dielectric layer pairs made of different materials and with different thicknesses in the dielectric stack 920. The dielectric stack 920 can be formed by one or more thin film deposition processes including, but not limited to, CVD, PVD, ALD, or any combination thereof.

In some implementations, the first dielectric layers 922 can be oxide layers, and the second dielectric layer 924 can be nitride layers. That is, the dielectric stack 920 can include a plurality of oxide/nitride layer pairs. It is noted that, the oxide layers 922 and/or nitride layers 924 can include any suitable oxide materials and/or nitride materials. In some implementations, the oxide layers can be silicon oxide layers, and the nitride layers can be silicon nitride layer. The plurality of oxide/nitride layer pairs are also referred to herein as an “oxide/nitride stack.” That is, in the dielectric stack 920, multiple oxide layers 922 and multiple nitride layers 924 alternate in a vertical direction. In other words, except a top and a bottom layer of a given alternating oxide/nitride stack, each of the other oxide layers 922 can be sandwiched by two adjacent nitride layers 924, and each of the nitride layers 924 can be sandwiched by two adjacent oxide layers 922.

Oxide layers 922 can each have the same thickness or have different thicknesses. For example, a thickness of each oxide layer can be in a range from about 10 nm to about 150 nm. Similarly, nitride layers 924 can each have the same thickness or have different thicknesses. For example, a thickness of each nitride layer can be in a range from about 10 nm to about 150 nm. In some implementations, a total thickness of the dielectric stack 920 can be larger than 1000 nm. It is noted that, the thickness ranges are provided for illustration, and should not be construed to limit the scope of the appended claims.

The dielectric stack 920 can include any suitable number of layers of the oxide layers 922 and the nitride layers 924. In some implementations, a total number of layers of the oxide layers 922 and the nitride layers 924 in the dielectric stack 920 is equal to or larger than 16. That is, a number of oxide/nitride layer pairs can be equal to or larger than 8. In some implementations, alternating oxide/nitride stack includes more oxide layers or more nitride layers with different materials and/or thicknesses than the oxide/nitride layer pair. For example, a bottom layer and a top layer in the dielectric stack 920 can be oxide layers 922.

As shown in FIGS. 9A-9B, the plurality of through holes 940 can be formed in the dielectric stack 920. In some implementations, a first array of through holes 940 can be formed in a first array region 991 of the dielectric stack 920, and a second array of through holes 940 can be formed in a second array region 994 of the dielectric stack 920. Each through hole 940 can extend vertically through the dielectric stack 920 and expose the substrate 910. In some implementations, the through holes 940 can have a high aspect ratio, and can be formed by etching the dielectric stack 920, and a subsequent cleaning process. The etching process to form the through holes 940 can include a wet etching, a dry etching, or a combination thereof. In some implementations, each through hole 940 can have an oval in the X-Y plane. The long diameter of each through hole 940 can be along the second lateral direction (e.g., Y-direction), and the short diameter of each through hole 940 can be along the first lateral direction (e.g., X-direction).

As shown in FIG. 9B, a plurality of first slits 928 can be formed at both sides of the plurality of through holes 940. Each slit 928 can laterally extend along the second lateral direction (e.g., Y-direction) and vertically through the dielectric stack 920 and expose the substrate 910. In some implementations, the first slits 928 can have a high aspect ratio, and can be formed by etching the dielectric stack 920, and a subsequent cleaning process. The etching process to form the first slits 928 can include a wet etching, a dry etching, or a combination thereof. In some implementations, the through holes 940 and the first slits 928 can be formed simultaneously in a same process.

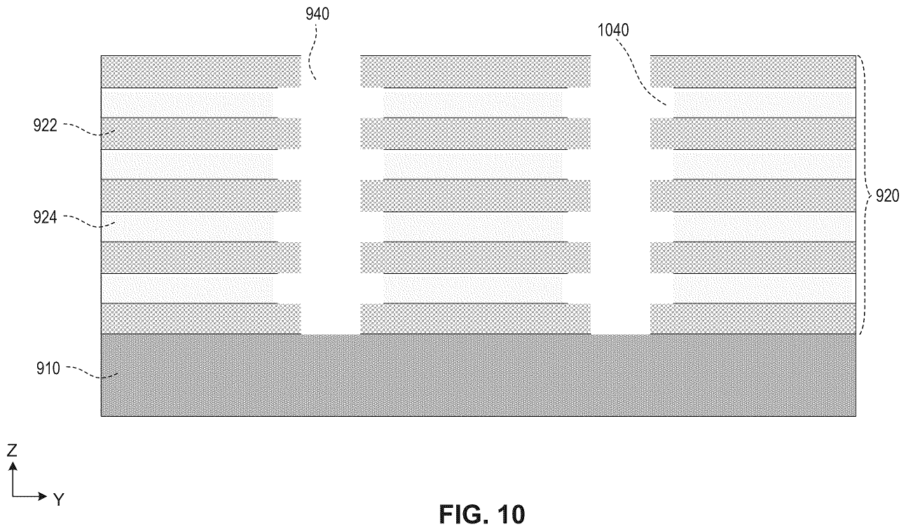

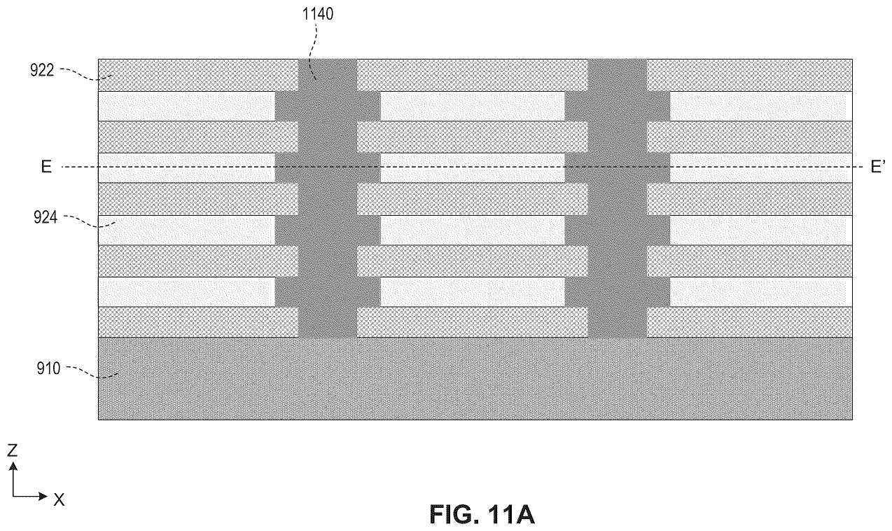

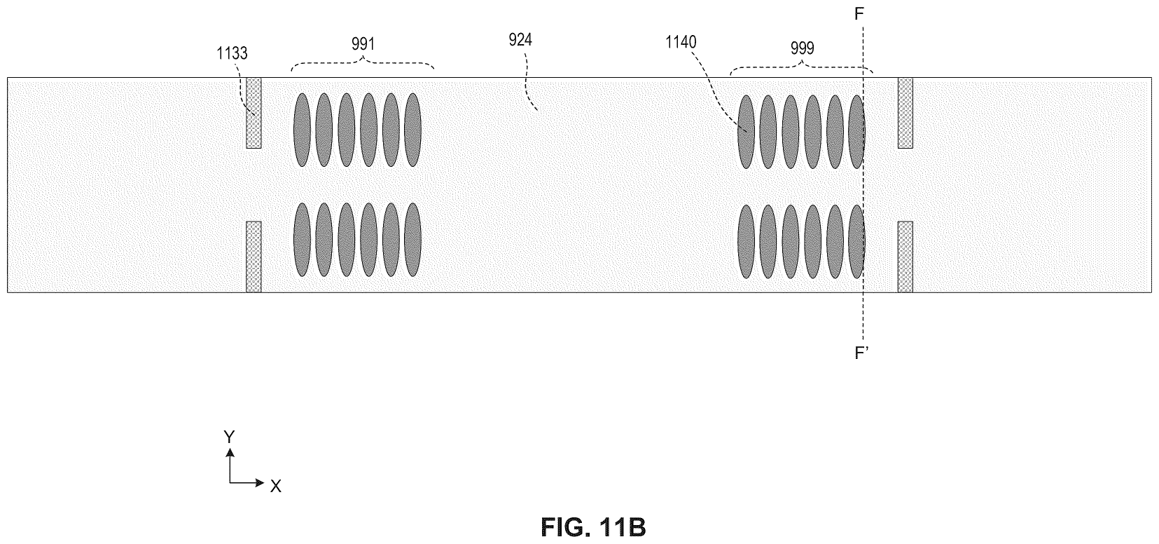

Referring to FIG. 8, method 800 proceeds to operation 804, in which sacrificial through structures can be formed in the through holes, and isolation walls can be formed in the slits. FIG. 10 illustrates a schematic cross-sectional view of the 3D memory structure during an intermedia step of operation 802 along the FF′ line of FIG. 9B, according to some implementations of the present disclosure. FIG. 11A illustrates a schematic cross-sectional view of the 3D memory structure after operation 804 along the FF′ line of FIG. 11B, according to some implementations of the present disclosure. FIG. 11B illustrates a schematic top view of the 3D memory structure after operation 804 along the EE′ line of 11A, according to some implementations of the present disclosure.

As shown in FIG. 10, operation 804 can include a recess etching process to remove portions of the second dielectric layers 924 of the dielectric stack 920 that are exposed by the plurality through holes 940. As such, a plurality of recesses 1040 can be formed on the sidewall of each through hole 940.

In some implementations, portions of the second dielectric layers 924 of the dielectric stack 920 on the sidewall of each through hole 940 can be removed by using any suitable etching process, e.g., an isotropic dry etch or a wet etch. The etching process can have sufficiently high etching selectivity of the material of the second dielectric layers 924 over the materials of the first dielectric layers 922, such that the etching process can have minimal impact on the first dielectric layers 922. The isotropic dry etching and/or the wet etching can remove portions of the second dielectric layers 924 that are exposed by the multiple through holes 940. As such, multiple recesses 1040 can be formed on the sidewall of each through hole 940.

In some implementations, each recess 1140 can have a horizontal hollow ring shape, with an outer sidewall as the second dielectric layer 924 as well as a top wall and a bottom wall as the adjacent first dielectric layers 922. That is, after the recess etching process, each through hole 940 can have an uneven sidewall. In some implementations, the size of the etch back of the second dielectric layer 924 can be in a range from about 5 nm to about 20 nm.

As shown in FIG. 11A, operation 804 can further include a deposition process to form a plurality of sacrificial through structures 1140 in the through holes 940. In some implementations, the sacrificial through structures 1140 can be formed to fill the through holes 940 and the multiple recesses 1040 on the sidewalls of the through holes 940. In some implementations, the formation of the sacrificial through structures 1140 can include filling a sacrificial material (e.g., polysilicon) into the through holes 940 by using any suitable deposition process, such as ALD, CVD, PVD, etc.

As shown in FIG. 11B, operation 804 can further include a deposition process to form a plurality of isolation walls 1133 in the first slits 928. In some implementations, the sacrificial isolation walls 1133 can include any suitable insulating material (e.g., silicon oxide) and can be formed to fill the first slits 928 by using any suitable deposition process, such as ALD, CVD, PVD, etc.

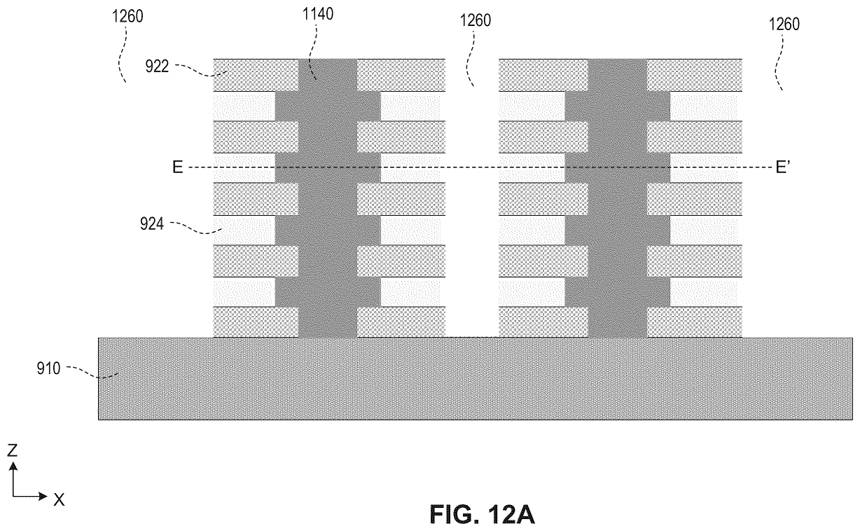

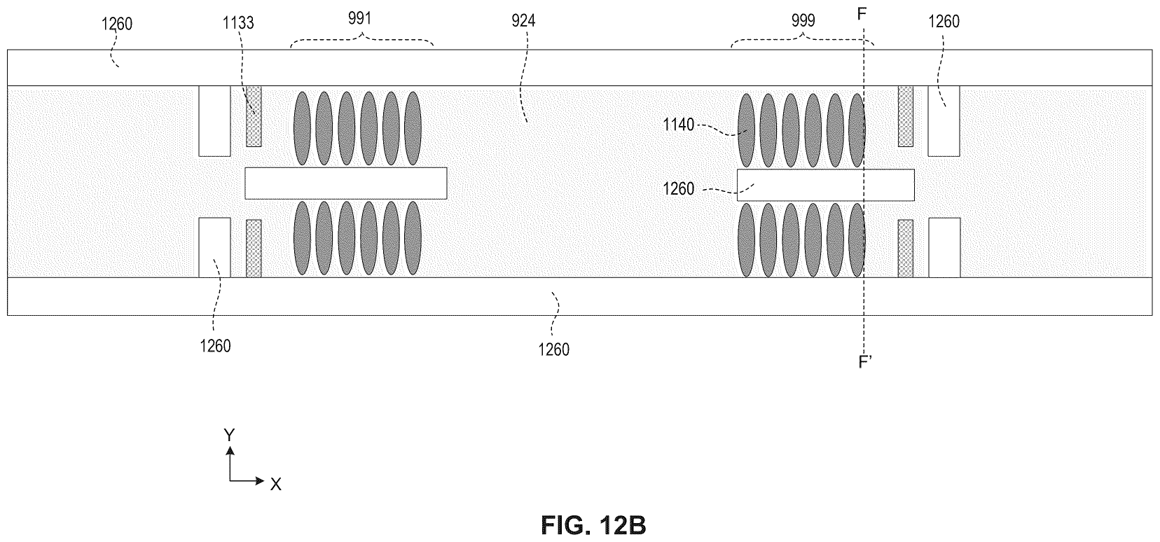

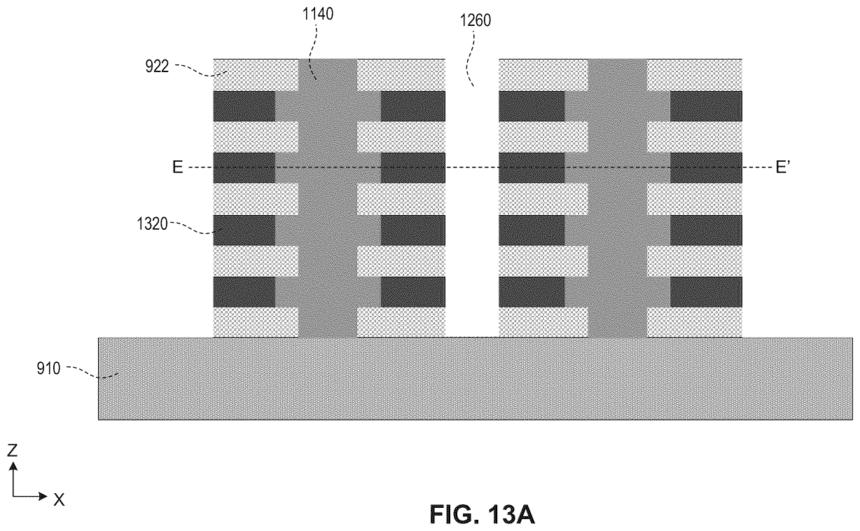

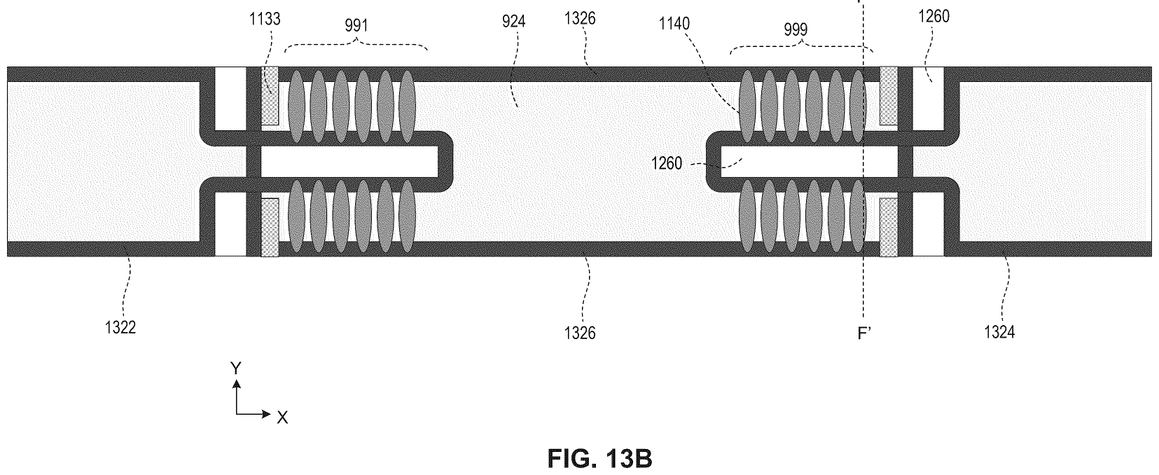

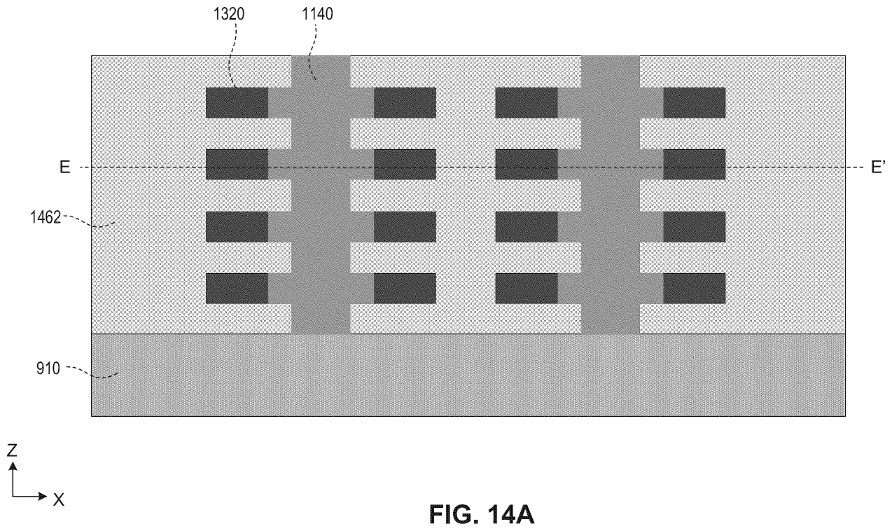

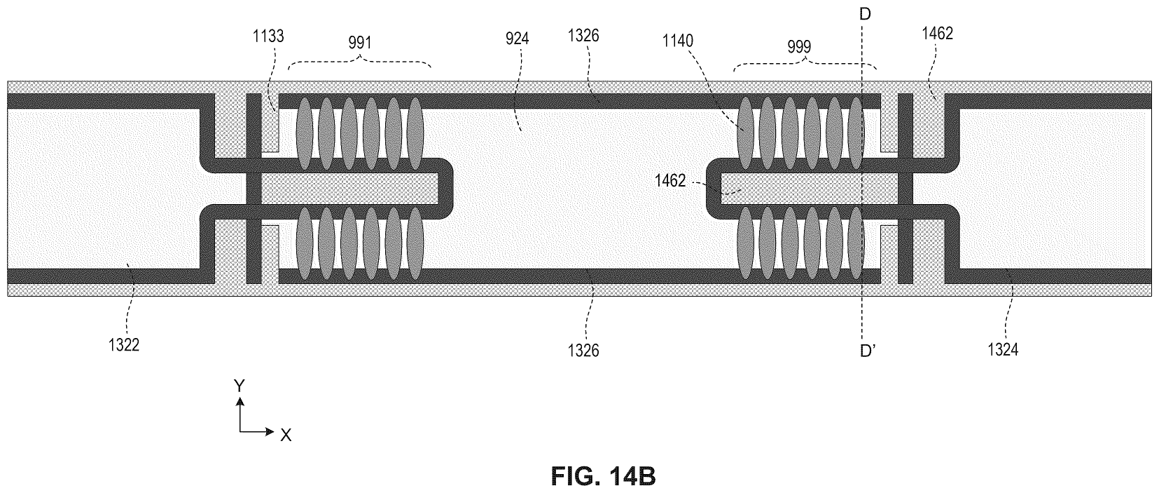

Referring to FIG. 8, method 800 proceeds to operation 806, in which a plurality of conductive lines can be formed. FIG. 12A illustrates a schematic cross-sectional view of the 3D memory structure during a first intermedia step of operation 806 along the FF′ line of FIG. 12B, according to some implementations of the present disclosure. FIG. 12B illustrates a schematic top view of the 3D memory structure during the first intermedia step of operation 806 along the EE′ line of 12A, according to some implementations of the present disclosure. FIG. 13A illustrates a schematic cross-sectional view of the 3D memory structure during a second intermedia step of operation 806 along the FF′ line of FIG. 13B, according to some implementations of the present disclosure. FIG. 13B illustrates a schematic top view of the 3D memory structure during the second intermedia step of operation 806 along the EE′ line of 13A, according to some implementations of the present disclosure. FIG. 14A illustrates a schematic cross-sectional view of the 3D memory structure after operation 806 along the FF′ line of FIG. 14B, according to some implementations of the present disclosure. FIG. 14B illustrates a schematic top view of the 3D memory structure after operation 806 along the EE′ line of 14A, according to some implementations of the present disclosure.

As shown in FIGS. 12A-12B, operation 806 can include removing portions of the dielectric stack 920 to form a plurality of slits 1260. The pattern of the second slits 1260 in the lateral X-Y plane can be pre-determined by the conductive lines formed in a subsequent step. In the vertical direction (e.g., Z-direction), the second slits 1260 can be formed to penetrate the dielectric stack 920. In some implementations, the second slits 1260 can be formed by forming a mask layer (not shown) over the dielectric stack 920, and patterning the mask layer using, e.g., photolithography, to form openings corresponding to the plurality of slits in the patterned mask layer. A suitable etching process, e.g., dry etch and/or wet etch, can be performed to remove portions of dielectric stack 920 exposed by the openings until the slits 1260 expose the substrate 910. The mask layer can be removed after the formation of the plurality of slits 1260.

As shown in FIGS. 13A-13B, operation 806 can further include replacing portions of the second dielectric layers 924 of the dielectric stack 920 exposed by the plurality of second slits 1260 by conductive lines 1320 (including 1322, 1324, 1326). In some implementations, portions of the second dielectric layers 924 of the dielectric stack 920 exposed by the plurality of slits 1260 can be removed to form multiple horizontal trenches (not shown). In some implementations, the exposed portions of the second dielectric layers 924 can be removed by using any suitable recess etching process, e.g., an isotropic dry etch or a wet etch. The etching process can have sufficiently high etching selectivity of the material of the second dielectric layers 924 over the materials of the first dielectric layers 922 of the dielectric stack 920 and the sacrificial through structures 1140, such that the etching process can have minimal impact on the first dielectric layers 922 and the sacrificial through structures 1140.

In some implementations, the recess etching process can remove portions of second dielectric layers 924 in various directions through the plurality of slits 1260. As such, multiple horizontal trenches (not shown) can then be formed to extend in a horizontal direction into a certain depth recessing from the sidewalls of the plurality of slits 1260. After portions of the second dielectric layers 924 are removed, the multiple slits 1260 and multiple horizontal trenches can be cleaned by using any suitable cleaning process.

After the cleaning process, in some implementations, conductive lines 1320 (including 1322, 1324, 1326) can be formed in the multiple horizontal trenches, as shown in FIGS. 13A-13B. The conductive lines 1320 (including 1322, 1324, 1326) can be formed by filling the multiple horizontal trenches with any suitable conductive material, e.g., tungsten, aluminum, copper, cobalt, or any combination thereof. The conductive material can be deposited into horizontal trenches using a suitable deposition method such as CVD, PVD, plasma-enhanced CVD (PECVD), sputtering, metal-organic chemical vapor deposition (MOCVD), and/or ALD. In some implementations, the formed conductive lines 1320 (including 1322, 1324, 1326) can be used as source and drain terminals of the FeFETs formed in subsequent processes, according to some implementations of the present disclosure. In some implementations, the first/second common first-type terminal lines 1322/1324 can be isolated from the common second-type terminal lines 1326 by isolation walls 1133, as shown in FIG. 13B.

As shown in FIGS. 14A-14B, operation 806 can further include forming filling structures 1462 to fill the plurality of second slits 1260. In some implementations, after forming the conductive lines 1320 (including 1322, 1324, 1326), the plurality of second slits 1260 can be filled by a dielectric material using any suitable deposition method such as CVD, PVD, and/or ALD. In some implementations, the dielectric material of the filling structures 1462 can be a low temperature oxide material. In some implementations, the dielectric material of the filling structures 1462 can include the same dielectric material of the first dielectric layer 922, such as silicon oxide.

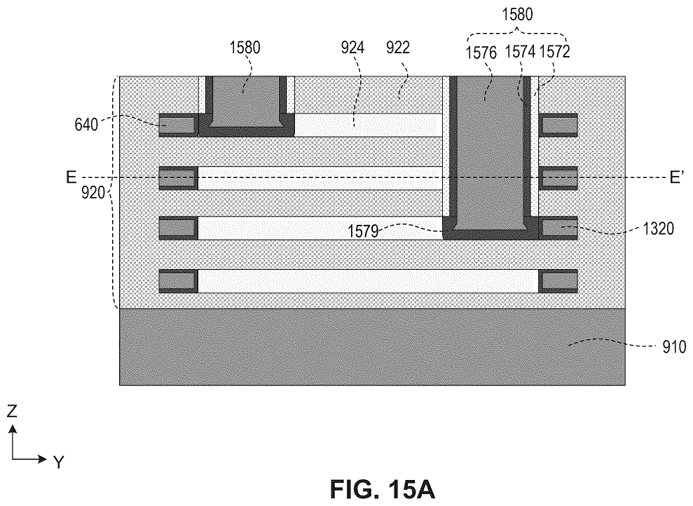

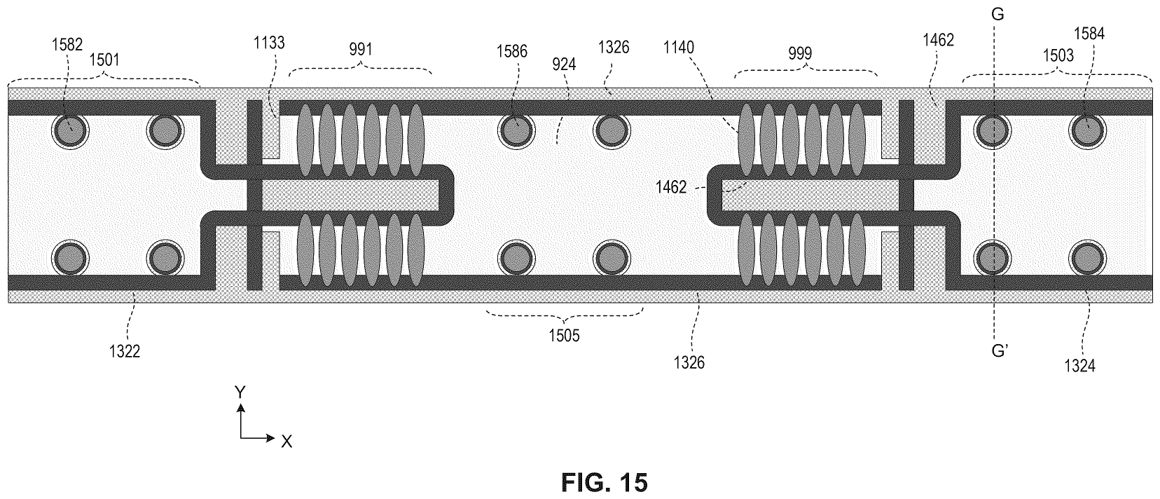

Referring to FIG. 8, method 800 can process to operation 808, in which a plurality of contact structures can be formed in contact regions. FIG. 15A illustrates a schematic cross-sectional view of the 3D memory structure after operation 808 along the GG′ line of FIG. 15B, according to some implementations of the present disclosure. FIG. 15B illustrates a schematic top view of the 3D memory structure after operation 808 along the EE′ line of 15A, according to some implementations of the present disclosure.

As shown in FIGS. 15A-15B, a plurality of contact structures 1580 (including 1582, 1584, 1586) can be formed in the contact regions 1501, 1503, and 1505. The first common first-type terminal contact structures 1582 can be formed to contact with the first common first-type terminal lines 1322 and located in the first first-type terminal contact region 1501 at a first lateral side of the first array region 991 away from the second array region 999. The second common first-type terminal contact structures 1584 can be formed to contact with the second common first-type terminal lines 1324 and located in the second first-type terminal contact region 1503 at a second lateral side of the second array region 999 away from the first array region 991. The common second-type terminal contact structures 1586 can be formed to contact with the common second-type terminal lines 1326 and located in the common second-type terminal contact region 1505 between the first array region 991 and the second array region 999.

As shown in FIG. 15A, forming the contact structures 1580 can include forming a plurality of contact holes each penetrating through an upper portion of the dielectric stack 920 and stopping at one corresponding second dielectric layer 924. A dielectric filling structure can be formed to fill each contact hole by any suitable deposition process. A punch etching can be performed to remove a portion of the dielectric filling structure to expose the one corresponding second dielectric layer 924 in each contact hole. The remaining portion of the dielectric filling structure forms a spacer layer 1572 on the sidewall of each contact hole. A portion of the corresponding one second dielectric layer 924 can be removed by any suitable etching process to expose one corresponding conductive line 1320 at a same level of the corresponding one second dielectric layer 924. A conductive layer 1574 can be formed by any suitable thin film deposition process to cover the spacer layer 1572 and the bottom surface of each contact hole, and in contact with the one corresponding conductive line 1320 in a lateral direction. A second conductive material can then be filled in the contact hole to form a conductive filling structure 1576. The conductive layer 1574 and the conductive filling structure 1576 can form a conductive via isolated from other conductive lines 1320 by the spacer layer 1572.

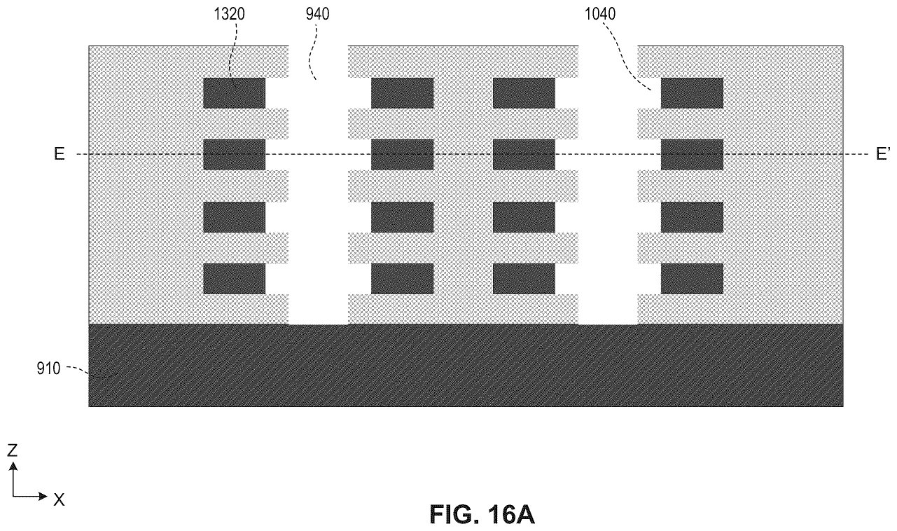

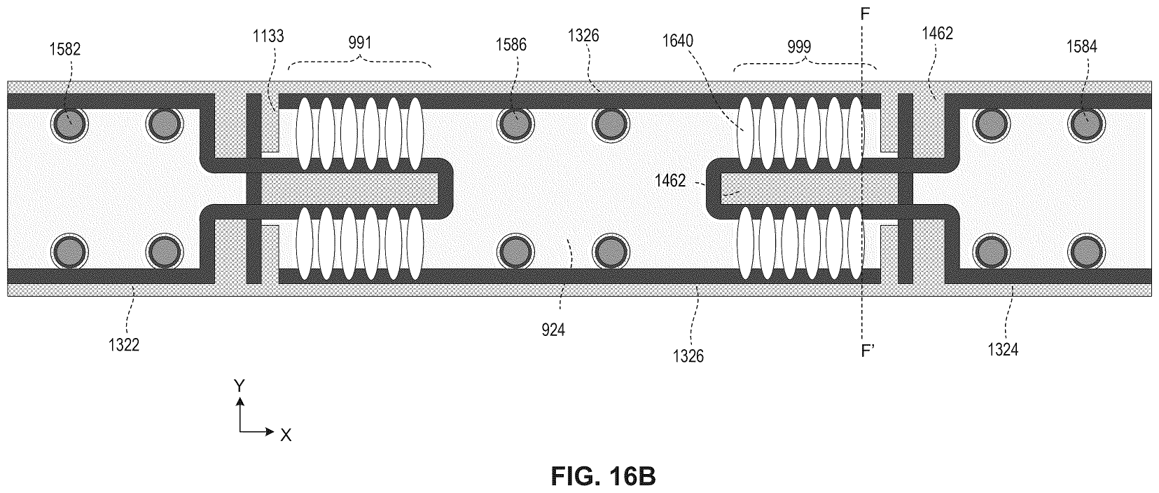

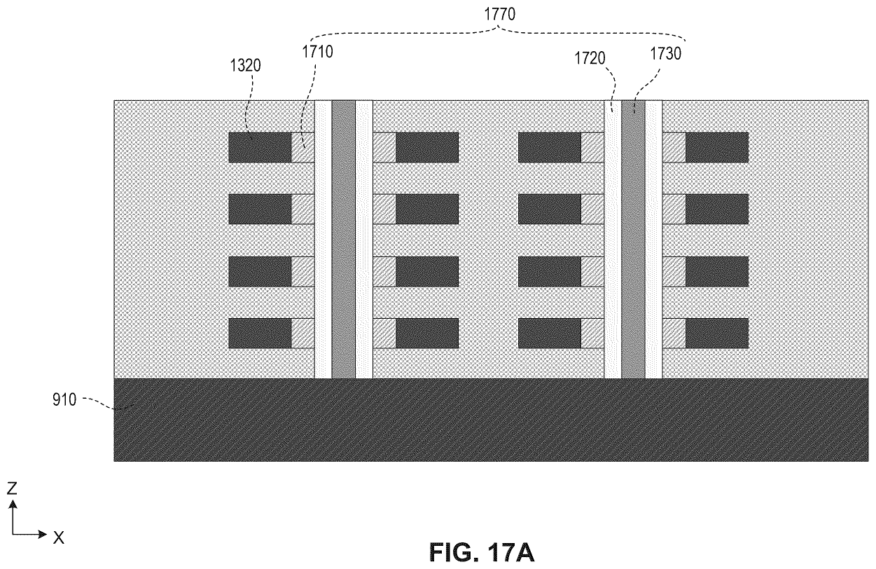

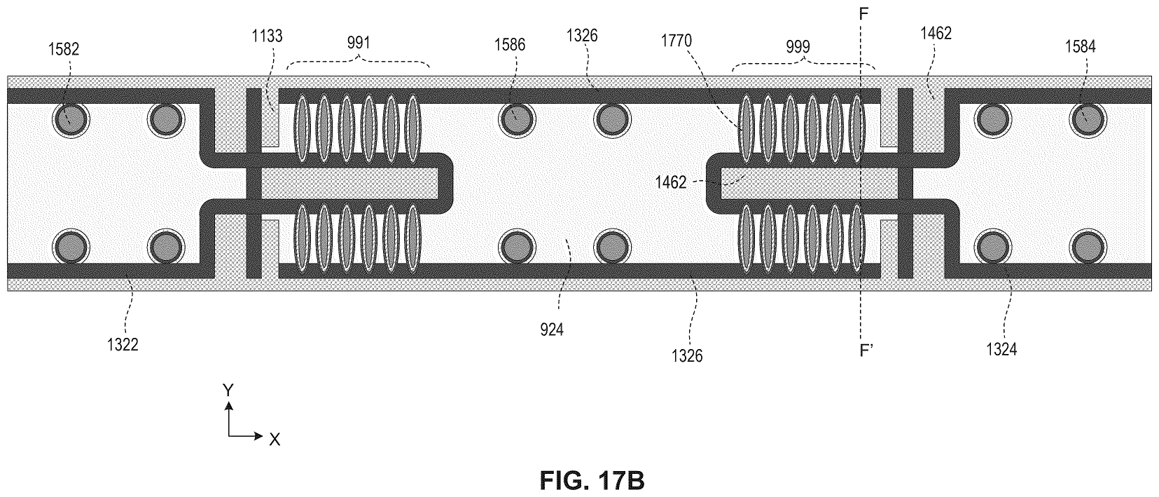

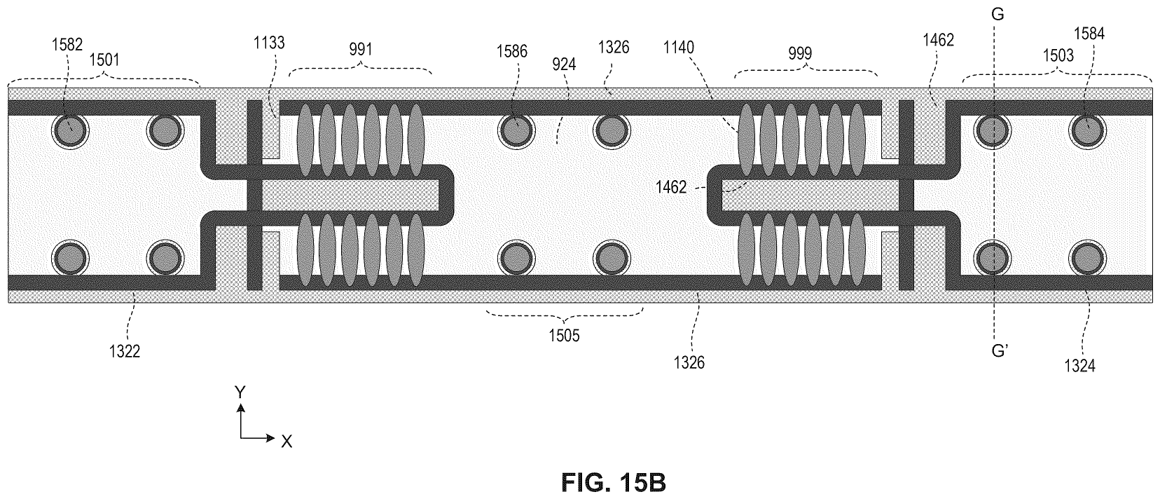

Referring to FIG. 8, method 800 can process to operation 810, in which the plurality of sacrificial through structures can be replaced by a plurality of transistor structures. FIG. 16A illustrates a schematic cross-sectional view of the 3D memory structure during an intermedia step of operation 810 along the FF′ line of FIG. 16B, according to some implementations of the present disclosure. FIG. 16B illustrates a schematic top view of the 3D memory structure during the intermedia step of operation 810 along the EE′ line of 16A, according to some implementations of the present disclosure. FIG. 17A illustrates a schematic cross-sectional view of the 3D memory structure after operation 810 along the FF′ line of FIG. 17B, according to some implementations of the present disclosure. FIG. 17B illustrates a schematic top view of the 3D memory structure after operation 810 along the EE′ line of 17A, according to some implementations of the present disclosure.

As shown in FIGS. 16A-16B, operation 810 can include removing the sacrificial through structures 1140 to reopen the plurality through holes 940 and the plurality of recesses 1040 on the sidewalls of the through holes 940. In some implementations, the sacrificial through structures 1140 can be removed by using any suitable etching process, e.g., an isotropic dry etch or a wet etch. The etching process can have sufficiently high etching selectivity of the material of the sacrificial through structures 1140 over the materials of the first dielectric layers 922 and the conductive lines 1320, such that the etching process can have minimal impact on the first dielectric layers 922 and the conductive lines 1320. After removing the sacrificial through structures 1140, the plurality through holes 940 and the plurality of recesses 1040 on the sidewalls of the through holes 940 can be reformed. That is, new through holes 1640 can have unsmooth sidewalls and expose conductive lines 1320, as shown in FIG. 16A.

As shown in FIG. 17A-17B, operation 810 can further include forming transistor structures 1770 in the new through holes 1640. In some implementations, the transistor structure 1770 can include a control gate 1730 extending vertically through the new through hole 1640, a ferroelectric layer 1720 laterally encircling the control gate 1730, and a plurality of channel layers 1710 laterally encircling the ferroelectric layer 1720.

The channel layers 1710 can be formed in the plurality of recesses 1040 of each new through hole 1640. In some implementations, the formation of the channel layers 1710 can include a deposition process to form a silicon layer to cover the sidewalls of the plurality of new through holes 1640. The silicon layer can be an amorphous silicon layer or a polysilicon layer formed by using a thin film deposition process, such as ALD, CVD, PVD, or any other suitable process. In some implementations, the formation of the channel layers 1710 can further include an etch process to remove portions of the silicon layer attached on the sidewall of the first dielectric layers 922. As such, the remaining portions of the silicon layer in the plurality of recesses 1040 can form the channel layers 1710, as shown in FIG. 17A.

In some implementations as shown in FIG. 17B, each layer of the channel layers 1710 can be in contact with the first/second common first-type terminal lines 1322/1324, and in contact with the common second-type terminal lines 1326. The first/second common first-type terminal lines 1322/1324 can be in contact with the channel layer 1710 at one end of the long diameter of each through structure 1770, such as the lower ends of the first row of through structures 1770 and the upper ends of the second row of through structures 1770. The common second-type terminal lines 1326 can be in contact with the channel layer 1710 of each through structure 1770 at the other end of the long diameter of each through structure 1770, such as the upper ends of the first row of through structures 1770 and the lower ends of the second row of through structures 1770. Therefore, the first/second common first-type terminal lines 1322/1324 and the common second-type terminal lines 1326 can be used as the common bit lines and the common source lines, respectively.

In some implementations, a memory film can be formed in each new through hole 1640. In some implementations, the memory film can include a barrier layer (now shown), a ferroelectric layer 1720, and an interface layer (not shown).

In some implementations, the interface layer 1668 can be formed on the sidewall and the bottom of each new through hole 1640. The sidewall of the interface layer can be in contact with the first dielectric layers 922 and the channel layers 1710. The bottom side of the interface layer can be in contact with substrate 910. The interface layer can be used to reduce the possibility of material intermixing between the ferroelectric layer 1720 and the channel layers 1710. In some implementations, the interface layer can be silicon oxide, silicon nitride, silicon oxynitride, high-k dielectric material (e.g., HfO₂, HfAlO, Al₂O₃), and/or any combination thereof. The interface layer can be formed by any suitable film deposition technique (e.g., ALD, CVD, sputtering, evaporation, and/or any combination thereof), or formed by oxidation, nitridation, and/or a combination thereof. The thickness of the interface layer can be in a range between about 5 nm and about 50 nm.

In some implementations, the ferroelectric layer 1720 can be formed to cover the interface layer. In some implementations, the ferroelectric layer 124 can include a metal oxide semiconductor material, such as indium gallium zinc oxide (IGZO). In some implementations, the ferroelectric layer 1720 can include a high-k (i.e., high dielectric constant) dielectric material, which can include transitional metal oxides such as hafnium-zirconium oxide (HZO), hafnium oxide (HfO₂), aluminum oxide (Al₂O₃), Zirconium oxide (ZrO₂), titanium oxide (TiO₂), niobium oxide (Nb₂O₅), tantalum oxide (Ta₂O₅), tungsten oxide (WO₃), molybdenum oxide (MO₃), vanadium oxide (V₂O₃), lanthanum oxide (La₂O₃), and/or any combination thereof.

In some implementations, the ferroelectric layer 1720 can be disposed by chemical vapor deposition (CVD), for example, metal organic chemical vapor deposition (MOCVD), low pressure chemical vapor deposition (LPCVD), plasma enhanced chemical vapor deposition (PECVD), high-density plasma chemical vapor deposition (HDP-CVD), etc. The ferroelectric layer 1720 can also be disposed by atomic layer deposition (ALD), sputtering, evaporating, or any combination thereof. In some implementations, the ferroelectric layer 1720 can have a thickness in a range between 5 nm and 100 nm.

In some implementations, to improve the ferroelectric property, the high-k dielectric material of the ferroelectric layer 1720 can be doped. For example, the ferroelectric layer 1720 can be HZO or HfO₂ doped with silicon (Si), (Yttrium) Y, Gadolinium (Gd), Lanthanum (La), Zircomium (Zr) or Aluminum (Al), or any combination thereof. In some implementations, the ferroelectric film 224 can include Zirconate Titanate (PZT), Strontium Bismuth Tantalate (SrBi₂Ta₂O₉), Barium Titanate (BaTiO₃), PbTiO₃, and BLT ((Bi,La)₄Ti₃O₁₂), or any combination thereof.

In some implementations, the barrier layer can be formed to cover the ferroelectric layer 1720. The barrier layer can be used to block the interactions between the ferroelectric layer 1720 and a control gate formed in a subsequent process. The barrier layer can include titanium nitride (TiN), silicon oxide (SiO₂), silicon nitride (Si₃N₄), silicon oxynitride (Si₂O₂N), high-k dielectric materials (e.g., HfO₂, Al₂O₃), and/or any combination thereof. The barrier layer can be formed by any suitable physical vapor deposition (PVD) or chemical vapor deposition (CVD). The barrier layer can have a thickness in a range between about 5 nm and about 50 nm.

In some implementations, as shown in FIG. 17A, the control gate 1730 can be formed in each new through hole 1640 to cover the memory film and fill the new through hole 1640. In some implementations, the control gate 1730 can be a metal filling structure or a polycrystalline silicon filling structure formed by using any suitable deposition process, such as ALD, CVD, PVD, etc. In some implementations, a following chemical-mechanical planarization (CMP) process can be performed to remove portions of the memory film and the control gates 1710 that are outside of the new through holes 1640.

Accordingly, three-dimensional (3D) Ferroelectric Field Effect Transistor (FeFET) Random Access Memory (RAM) devices, and fabricating methods thereof are described in the present disclosure. The disclosed 3D FeFET RAM devices are high-speed, high-density non-volatile memories by using ferroelectric polarity to change threshold voltage and store data. The graphical of the memory cells can be designed to be oval shape to increase the gate length for increasing gate control capability while increasing storage density. Further, the common source line and the common drain line can be formed to implement random access to each memory cell. The source and drain lines of each layer can be electrically connected by using though contacts, which simplifies the source-drain contact process. The drain/source electrodes of the FeFETs can be connected to common drain/source line to reduce staircase area. The ferroelectric material, such as IGZO, can be filled in the through hole from either front side or the back side as the channel material of the FeFETs, thereby improving the reliability of ferroelectric materials.

The foregoing description of the specific implementations will so fully reveal the general nature of the present disclosure that others can, by applying knowledge within the skill of the art, readily modify and/or adapt, for various applications, such specific implementations, without undue experimentation, and without departing from the general concept of the present disclosure. Therefore, such adaptations and modifications are intended to be within the meaning and range of equivalents of the disclosed implementations, based on the disclosure and guidance presented herein. It is to be understood that the phraseology or terminology herein is for the purpose of description and not of limitation, such that the terminology or phraseology of the present specification is to be interpreted by the skilled artisan in light of the disclosure and guidance.

Implementations of the present disclosure have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The Summary and Abstract sections can set forth one or more but not all implementations of the present disclosure as contemplated by the inventor(s), and thus, are not intended to limit the present disclosure and the appended claims in any way.

The breadth and scope of the present disclosure should not be limited by any of the above-described implementations, but should be defined only in accordance with the following claims and their equivalents.

What is claimed is:

1. A semiconductor structure, comprising:
a plurality of layers of transistors stacked in a vertical direction, each layer of transistors comprising:
a first array of transistors sharing a first common first-type terminal line;
a second array of transistors sharing a second common first-type terminal line, wherein the first array of transistors and the second array of transistors share a common second-type terminal line; and
a plurality of contact structures comprising:
a first common first-type terminal contact structure coupled with the first common first-type terminal line in a first first-type terminal contact region located on a first lateral side of the first array of transistors away from the second array of transistors,
a second common first-type terminal contact structure coupled with the second common first-type terminal line in a second first-type terminal contact region located on a second lateral side of the second array of transistors away from the first array of transistors, and
a common second-type terminal contact structure coupled with the common second-type terminal line in a common second-type terminal contact region located between the first array of transistors and the second array of transistors.

2. The semiconductor structure of claim 1, wherein the transistors are ferroelectric field-effect transistors (FeFET), each FeFET comprising:
a channel layer;
a ferroelectric layer having ferroelectricity and encircled by the channel layer in a horizontal plane; and
a gate encircled by the ferroelectric layer in the horizontal plane.

3. The semiconductor structure of claim 2, wherein:
the channel layer comprises a metal oxide semiconductor material; and
the channel layer of each FeFET has an oval-ring shape in a horizontal plane.

4. The semiconductor structure of claim 3, wherein:
a first portion of the channel layer at a second end of a long diameter of the oval shape is in contact with the first common first-type terminal line or the second common first-type terminal line; and
a second portion of the channel layer at a first end of the long diameter of the oval shape is in contact with the common second-type terminal line.

5. The semiconductor structure of claim 1, wherein:
the first common first-type terminal line comprises a first U-shape portion located between adjacent rows of the first array of transistors and with a first opening opposite towards the second array of transistors; and
the second common first-type terminal line comprises a second U-shape portion located between adjacent rows of the second array of transistors and with a second opening opposite towards the first array of transistors.

6. The semiconductor structure of claim 1, wherein:
the first-type terminal is a drain terminal;
the second-type terminal is a source terminal;
the first common first-type terminal contact structure is connected to a first bit line;
the second common first-type terminal contact structure is connected to a second bit line; and
the common second-type terminal contact structure is connected to a source line.

7. The semiconductor structure of claim 1, wherein:
each of the plurality of contact structures is located in a dielectric stack in the first first-type terminal contact region, or the second first-type terminal contact region, or the common second-type terminal contact region.

8. The semiconductor structure of claim 7, wherein:
the first common first-type terminal lines of the plurality of layers of transistors overlap in the vertical direction;
the second common first-type terminal lines of the plurality of layers of transistors overlap in the vertical direction; and
the common second-type terminal lines of the plurality of layers of transistors overlap in the vertical direction.

9. The semiconductor structure of claim 8, wherein one contact structure of an intermediate stack of transistors comprises:
a conductive via vertically extending in the dielectric stack above the intermediate stack of transistors;
a dielectric layer laterally surrounding the conductive via to isolate the contact structure from terminal lines of upper layers transistors above the intermediate stack of transistors; and
an enlarged conductive end laterally in electrical contact with a corresponding terminal line of the intermediate stack of transistors.

10. The semiconductor structure of claim 8, further comprising:
a first isolation wall between the first first-type terminal contact region and the first array of transistors to isolate the first common first-type terminal lines from the common second-type terminal lines; and
a second isolation wall between the second first-type terminal contact region and the second array of transistors to isolate the second common first-type terminal lines from the common second-type terminal lines.

11. A semiconductor structure, comprising:
a plurality of layers of transistors stacked in a vertical direction, each layer of transistors comprising:
a first array of transistors sharing a first common first-type terminal line;
a second array of transistors sharing a second common first-type terminal line, wherein the first array of transistors and the second array of transistors share a common second-type terminal line; and
a plurality of contact structures each coupled with the first common first-type terminal line, the second common first-type terminal line, or the common second-type terminal line,
wherein each of the plurality of contact structures electrically coupled with an intermediate stack of transistors penetrates through a dielectric stack above the intermediate stack of transistors.

12. The semiconductor structure of claim 11, wherein the transistors are ferroelectric field-effect transistors (FeFET), each FeFET comprising:
a channel layer;
a ferroelectric layer having ferroelectricity and encircled by the channel layer in a horizontal plane; and
a control gate encircled by the ferroelectric layer in the horizontal plane.

13. The semiconductor structure of claim 12, wherein:
the channel layer comprises a metal oxide semiconductor material; and
the channel layer of each FeFET cell has an oval-ring shape in a horizontal plane.

14. The semiconductor structure of claim 13, wherein:
a first portion of the channel layer at a second end of a long diameter of the oval shape is in contact with the first common first-type terminal line or the second common first-type terminal line; and
a second portion of the channel layer at a first end of the long diameter of the oval shape is in contact with the common second-type terminal line.

15. The semiconductor structure of claim 11, wherein:
the first common first-type terminal line comprises a first U-shape portion located between adjacent rows of the first array of transistors and with a first opening opposite towards the second array of transistors; and
the second common first-type terminal line comprises a second U-shape portion located between adjacent rows of the second array of transistors and with a second opening opposite towards the first array of transistors.

16. The semiconductor structure of claim 15, wherein the plurality of contact structures comprises:
a first common first-type terminal contact structure coupled with the first common first-type terminal line in a first first-type terminal contact region located on a first lateral side of the first array of transistors away from the second array of transistors,
a second common first-type terminal contact structure coupled with the second common first-type terminal line in a second first-type terminal contact region located on a second lateral side of the second array of transistors away from the first array of transistors, and
a common second-type terminal contact structure coupled with the common second-type terminal line in a common second-type terminal contact region located between the first array of transistors and the second array of transistors.

17. The semiconductor structure of claim 16, wherein:
the first-type terminal is a drain terminal;
the second-type terminal is a source terminal;
the first common first-type terminal contact structure is connected to a first bit line;
the second common first-type terminal contact structure is connected to a second bit line; and
the common second-type terminal contact structure is connected to a source line.

18. The semiconductor structure of claim 11, wherein each contact structure comprises:
a conductive via vertically extending in the dielectric stack above the intermediate stack of transistors;
a dielectric layer laterally surrounding the conductive via to isolate the contact structure from terminal lines of upper layers transistors above the intermediate stack of transistors; and
an enlarged conductive end laterally in electrical contact with a corresponding terminal line of the intermediate stack of transistors.

19. The semiconductor structure of claim 11, wherein:
the first common first-type terminal lines of the plurality of layers of transistors overlap in the vertical direction;
the second common first-type terminal lines of the plurality of layers of transistors overlap in the vertical direction; and
the common second-type terminal lines of the plurality of layers of transistors overlap in the vertical direction.

20. The semiconductor structure of claim 16, further comprising:
a first isolation wall between the first first-type terminal contact region and the first array of transistors to isolate the first common first-type terminal lines from the common second-type terminal lines; and
a second isolation wall between the second first-type terminal contact region and the second array of transistors to isolate the second common first-type terminal lines from the common second-type terminal lines.
